(19) United States
(12) Patent Application Publication
(10) Pub. No.: US 2013/0050226 A1
(43) Pub. Date: Feb. 28, 2013

(54) DIE-CUT THROUGH-GLASS VIA AND METHODS FOR FORMING SAME

(71) Applicants: Ravindra Vaman Shenoy, Dublin, CA (US); David William Burns, San Jose, CA (US); Kurt Edward Petersen, Milpitas, CA (US)

(72) Inventors: Ravindra Vaman Shenoy, Dublin, CA (US); David William Burns, San Jose, CA (US); Kurt Edward Petersen, Milpitas, CA (US)

(73) Assignee: QUALCOMM MEMS TECHNOLOGIES, INC., San Diego, CA (US)

(21) Appl. No.: 13/221,677

(22) Filed: Aug. 30, 2011

(51) Int. Cl. G06T 1/00; H05K 7/00; B05D 5/12; C23F 1/00; B32B 37/14; B32B 38/10; B05D 3/12; H05K 1/00; B05D 3/10

(52) U.S. Cl. 345/501; 174/258; 361/748; 427/58; 216/18; 156/250; 427/123

(57) ABSTRACT

This disclosure provides systems, methods and apparatus for providing electrical connections through glass substrates. In one aspect, a through-glass via including a peripheral through-glass via hole and sidewall metallization is provided. Sidewall metallization can include multiple conductive lines facilitating increased interconnect density. In another aspect, one or more methods of forming peripheral through-glass vias are provided. In some implementations, the methods include double-sided processes to form aligned via holes in a glass substrate that together form a through-glass via hole, followed by sidewall metallization and dicing through the through-glass via hole.

### TECHNICAL FIELD

This disclosure relates to structures and processes for glass substrates and more specifically to electrically conductive vias through the glass substrates.

### DESCRIPTION OF THE RELATED TECHNOLOGY

Electromechanical systems (EMS) include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

MEMS packaging protects the functional units of the system from the environment, provides mechanical support for the system components, and provides an interface for electrical interconnections.

### SUMMARY

The systems, methods and devices of the disclosure each have several innovative aspects, no single one of which is solely responsible for the desirable attributes disclosed herein.

One innovative aspect of the subject matter described in this disclosure includes apparatuses including one or more through-substrate vias. In some implementations, an apparatus includes a glass substrate having top and bottom surfaces and a plurality of side surfaces substantially orthogonal to and connecting the top and bottom surfaces, and a first through-glass via. The first through-glass via can include via openings in the top and bottom surfaces of the glass substrate, a sidewall and one or more electrically conductive pathways extending along the sidewall from the top surface to the bottom surface. In some implementations, the sidewall of a through-glass via is recessed from one or more of the side surfaces of the glass substrate. In some implementations, a sidewall of a through-glass via includes a first surface extending from the top surface and a second surface extending from the bottom surface, with the first and second surfaces intersecting at an intersection. Each of the first and second surfaces can be curved from a via opening to the intersection. The apparatus can include any number of through-glass vias according to the desired implementations.

In some implementations, the glass substrate can be joined to a second substrate. A device such as an electromechanical systems device can be disposed on the second substrate and in electrical communication with at least some of the one or more conductive pathways. In some implementations, the apparatus includes a seal between the glass substrate and the second substrate. An electromechanical systems device or other device can be sealed within an area defined at least in part by the glass substrate, the second substrate and the seal. The seal can include a bond such as, for example, a solder bond or an epoxy bond.

In some implementations, an electromechanical systems device can be disposed on the glass substrate and in electrical communication with at least some of the one or more conductive pathways. In some implementations, the apparatus includes a plurality of conductive lines extending along the sidewall from the top surface to the bottom surface of the glass substrate with at least some of the plurality of electrically conductive lines in electrical communication with bond pads disposed on the top or bottom surface of the glass substrate. In some implementations, the bond pads are arranged in a staggered formation. In some implementations, the apparatus includes a plurality of conductive lines having a pitch of no more than about 300 microns, for example, a pitch of no more than about 40 microns. The via openings can be half-slot shaped, for example.

In some implementations, an apparatus includes a display, a processor configured to communicate with the display and configured to process image data and a memory device configured to communicate with the processor.

Another innovative aspect of the subject matter described in this disclosure can be implemented in an apparatus with a glass substrate having first and second sides, a device mounted to the first side of the glass substrate, and means for electrically connecting the device to the second side of the glass substrate. For example, the apparatus may include means for connecting a microelectromechanical systems device to an electrical component on the second side of the glass substrate.

Another innovative aspect of the subject matter described in this disclosure can be implemented in methods of forming a peripheral through-substrate via. In some implementations, the methods include providing a glass substrate having first and second substantially planar parallel surfaces, forming a first via hole having sidewalls in the first surface and a second via hole having sidewalls in the second surface. The first and second via holes intersect to form a through-glass via hole having via openings at the first and second surfaces and an intersection dimension that is less than the corresponding dimension at each via opening. The methods can further include forming one or more electrically conductive lines that are continuous through the through-glass via hole from the first surface to the second surface; and dicing the glass substrate along a line that passes through the through-glass via hole.

In some implementations, the methods include double-sided processes to form aligned via holes in a glass substrate that together form a contoured through-glass via hole, followed by formation of one or more electrically conductive lines. Double-sided methods of forming the through-glass via hole include wet etching, dry etching, sandblasting or a combination of these techniques. Forming a through-glass via hole may include contouring the hole to form a direct line-of-sight region that facilitates deposition of a continuous conductive thin film through the through-glass via hole. Single-sided or double-sided sputtering or other deposition techniques may be used to deposit a conductive thin film in the through-glass via hole. In some implementations, forming one or more conductive lines includes use of an electrophoretic resist. In some implementations, forming one or more conductive lines includes a technique such as additive aerosol jetting of metal. Via metal thickness may be augmented with electro- or electroless plating. In some implementations, the formed conductive film or lines can be electrically isolated after metallization. The through-glass vias may optionally be filled, for example, with an electrically conductive material, a non-electrically conductive material, or a thermally conductive material.

In some implementations, the first and second via holes may each have a constant or variable radius of curvature. In some implementations, forming the first and second via holes includes exposing the first and second surfaces to a wet etchant. The method may further involve masking the first and second surfaces, the masks having at least one opening, the smallest of which is d_{M}. In some implementations, an etch radius of the first and second via holes satisfies R≧R_{Min} where R is the etch radius, and R_{Min}=(√2)(t_{S}/2)/(1+((d_{M}+R_{Min})/R_{Min})(1−(t_{S}/2R_{Min})²)^{1/2})^{1/2} with t_{S} being a thickness of the substrate.

In some implementations, the methods include joining the substrate to a second substrate prior to dicing the substrate. Also in some implementations, the methods involve metallizing at least one of the first and second substantially planar parallel surfaces to form one or more bond pads in electrical communication with the one or more continuous conductive lines.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIGS. 9A and 9B show examples of isometric and bottom views depicting a device including peripheral multi-trace through-glass vias.

FIG. 9C shows an example of a top view of a glass substrate including multiple dies and peripheral and non-peripheral through-glass vias prior to die singulation.

FIGS. 9D and 9E show examples of top and isometric views depicting a device including non-peripheral multi-trace through-glass vias.

FIGS. 10A-10E show examples of simplified cross-sectional schematic illustrations of glass substrates having peripheral through-glass vias.

FIG. 11 shows an example of a flow diagram illustrating a process for forming a peripheral through-glass via.

FIG. 12 shows an example of a flow diagram illustrating processes for forming through-glass via holes.

FIG. 13 shows an example of a cross-sectional schematic illustration of a through-glass via hole formed by double-sided wet etching.

FIGS. 14A-14D show examples of cross-sectional schematic illustrations of various stages of sandblasting methods of forming through-glass via holes.

FIGS. 14E and 14F show examples of cross-sectional schematic illustrations of various stages of dry etch methods of forming through-glass via holes.

FIG. 15 shows an example of a cross-sectional schematic illustration of a metallized contoured through-glass via hole.

FIG. 16 shows an example of a cross-sectional schematic illustration of certain etch parameters of a through-glass via hole.

FIG. 17 shows an example of cross-sectional schematic illustrations of a glass substrate at various stages of simultaneous etching of aligned via holes to form a through-glass via hole.

FIGS. 18A-20B present examples of isometric and cross-sectional views of implementations of circular, slot-shaped, and square-shaped through-glass via holes prior to metallization and dicing.

FIGS. 21A-21C show examples of schematic illustrations of sidewall metallization of peripheral through-glass vias.

FIG. 22 shows an example of a flow diagram illustrating a process for forming multiple conductive lines in a through-glass via hole.

FIGS. 23 and 24 show examples of flow diagrams illustrating processes for fabricating a glass package including a peripheral through-glass via.

FIGS. 25A-25F and 26A-26C show examples of schematic illustrations of various stages in a method of fabricating a glass package including a peripheral through-glass via.

FIGS. 27A and 27B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and/or electronic test equipment. Thus, the teachings are not intended to be limited to the implementations depicted solely in the Figures, but instead have wide applicability as will be readily apparent to one having ordinary skill in the art.

Some implementations described herein relate to packaging of MEMS devices and other devices using a glass or other substrates. While the following implementations will focus on glass substrates, it is understood that other substrates may also be used. Through-substrate vias, which include electrical connections extending through a substrate such as a glass panel or other glass substrate, and fabrication methods related to through-substrate vias are described herein. While implementations of the methods of fabrication and the resulting through-substrate vias are described chiefly in the context of glass packaging of MEMS and other devices, including other electromechanical systems devices (EMS) and integrated circuit (IC) devices, the methods and vias are not so limited and may be implemented in other contexts that employ a conductive path through any electrically insulating substrate such as glass.

Some implementations described herein relate to glass substrates having peripheral vias as well as apparatuses that include such peripheral vias. In some implementations, a glass substrate includes a top and bottom surfaces and a plurality of peripheral surfaces. A through-glass via can include via openings in the top and bottom surfaces and a sidewall recessed from one or more of the peripheral surfaces. One or more conductive pathways extend along the sidewall from the top surface to the bottom surface. The conductive pathways can provide an electrical connection between one or more traces, pads, ICs, EMS devices or other electrically active component on the top surface of the glass substrate and one or more traces, pads, ICs, EMS devices or other electrically active component on the bottom surface of the glass substrate. In some implementations, a conductive pathway can include a thin film coating all or a portion of the via hole sidewall. In some implementations, the through-glass via (e.g. a peripheral multi-trace through-glass via or a non-peripheral multi-trace through-glass via) includes a plurality of conductive lines extending from the top surface of the glass substrate to the bottom surface.

In some implementations, a glass substrate including one or more peripheral or non-peripheral through-glass vias is joined to one or more additional substrates. The substrates can be joined, for example, by a solder bond or an epoxy bond. In some implementations, an electromechanical systems device is disposed on an additional substrate that is joined to the glass substrate. The electromechanical systems device can be in electrical communication with one or more conductive pathways of a peripheral or non-peripheral through-glass via of the glass substrate. In some implementations, the glass substrate can cover the electromechanical device. In some implementations, a peripheral or non-peripheral through-glass via can be a back interconnect for an electromechanical systems device.

In some implementations, a peripheral or non-peripheral through-glass via in a glass substrate includes a plurality of conductive lines. At least some of the plurality of conductive lines can be in electrical communication with bond pads disposed on the top or bottom surface of the glass substrate. The conductive lines can be spaced apart and have a pitch of, for example, between about 40 and 300 microns. The bond pads can be arranged in a staggered formation to facilitate increased line density.

Methods of fabricating peripheral and non-peripheral through-glass vias are described herein. In some implementations, the methods involve forming a through-glass via hole in a glass substrate, followed by metallizing a sidewall of the through-glass via hole and dicing the glass substrate along a line that passes through the through-glass via hole. In some implementations, forming through-glass via holes includes a double-sided process to form aligned etched recesses on opposite sides of a glass substrate with the etched recesses together forming a through-glass via hole. Metallizing a sidewall can include forming multiple spaced-apart conductive lines by an appropriate technique such as jetting or spraying metal or metal particles. In some implementations, an electrophoretic resist is used to pattern conductive lines in a through-glass via hole.

Particular implementations of the subject matter described in this disclosure can be implemented to realize one or more of the following potential advantages. In some implementations, batch panel-level processing methods can be used to eliminate or reduce die-level processing. Advantages of encapsulation and packaging in a batch process at a panel or sub-panel level include a large number of units fabricated in parallel in the batch process, thus reducing costs per unit as compared to individual die level processing. The use of batch processes such as lithography, etching and plating over a large substrate in some implementations allows tighter tolerances and reduces die-to-die variation. The formation of through-glass interconnections in a single two-sided plating process stage can reduce costs per package. In some implementations, smaller and/or more reliably packaged devices (including MEMS devices) can be fabricated. Smaller devices can result in a larger number of units fabricated in parallel in the batch process. In some implementations, package-related stresses on a MEMS or other device can be reduced or eliminated. For example, in some implementations, concerns related to mold process stresses on, for example, a MEMS device can be eliminated by providing a cover glass with surface mount pads without molding.

An example of a suitable electromechanical systems (EMS) or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

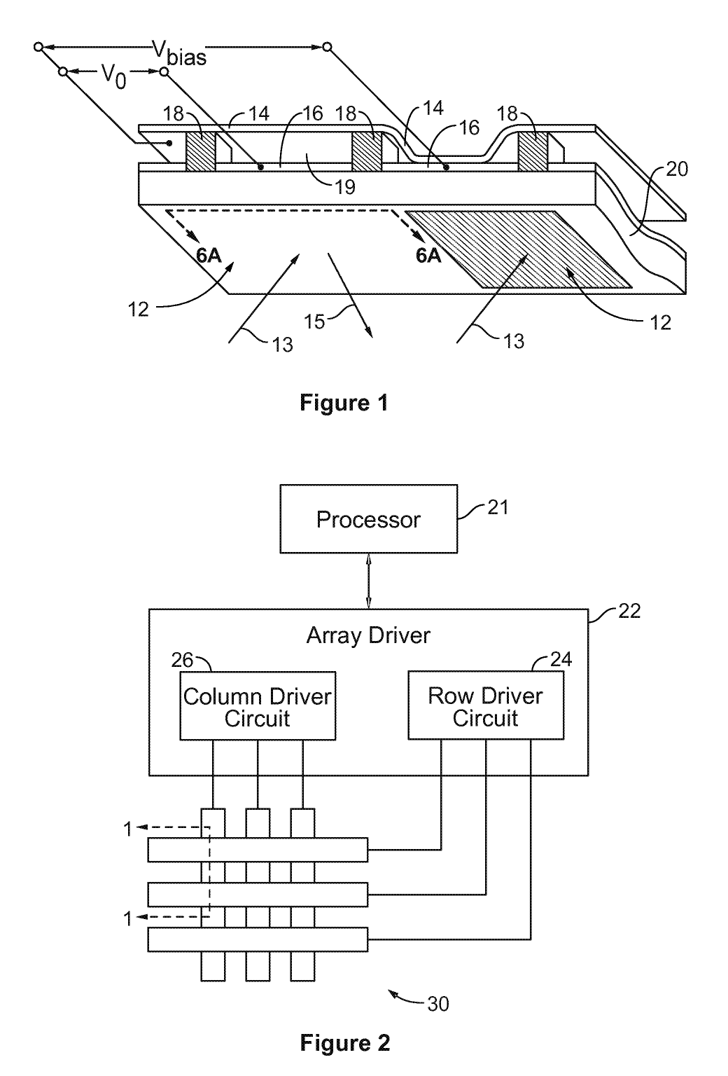

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be approximately less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

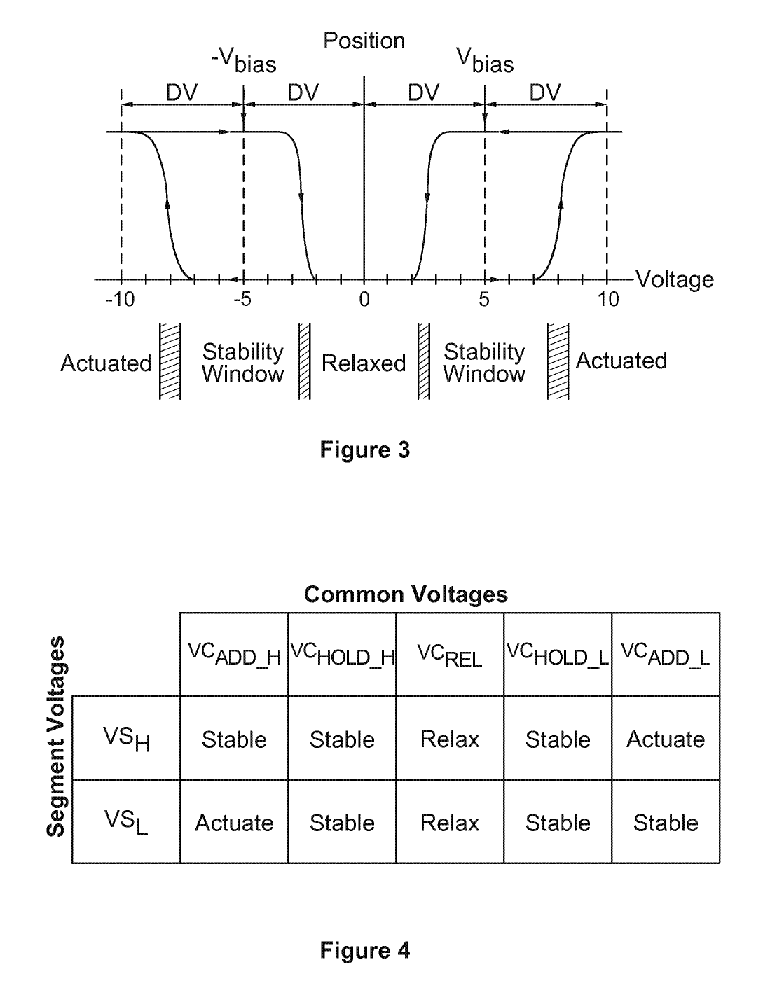

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

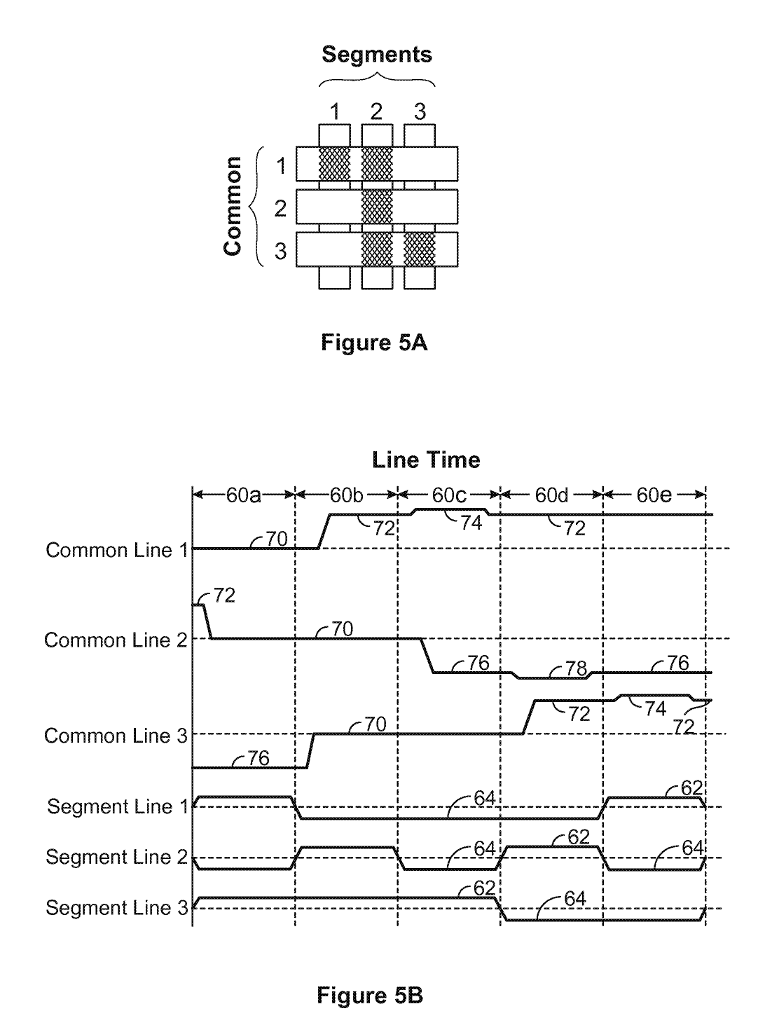

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

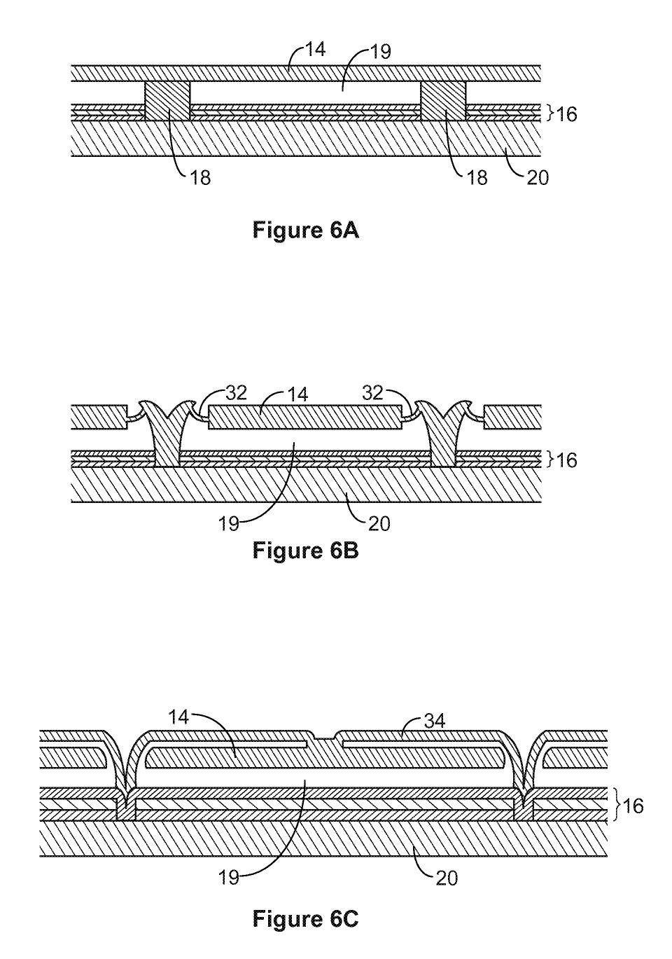

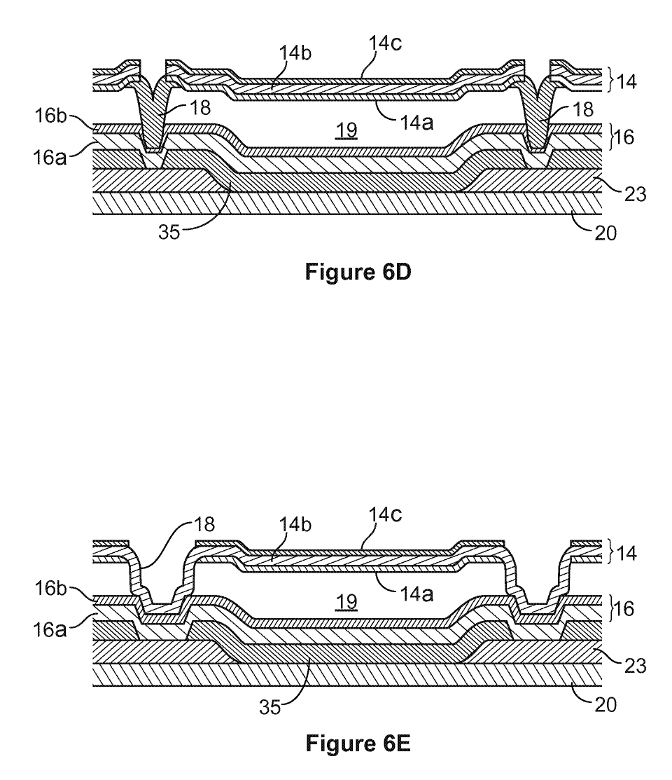

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoride (CFO and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

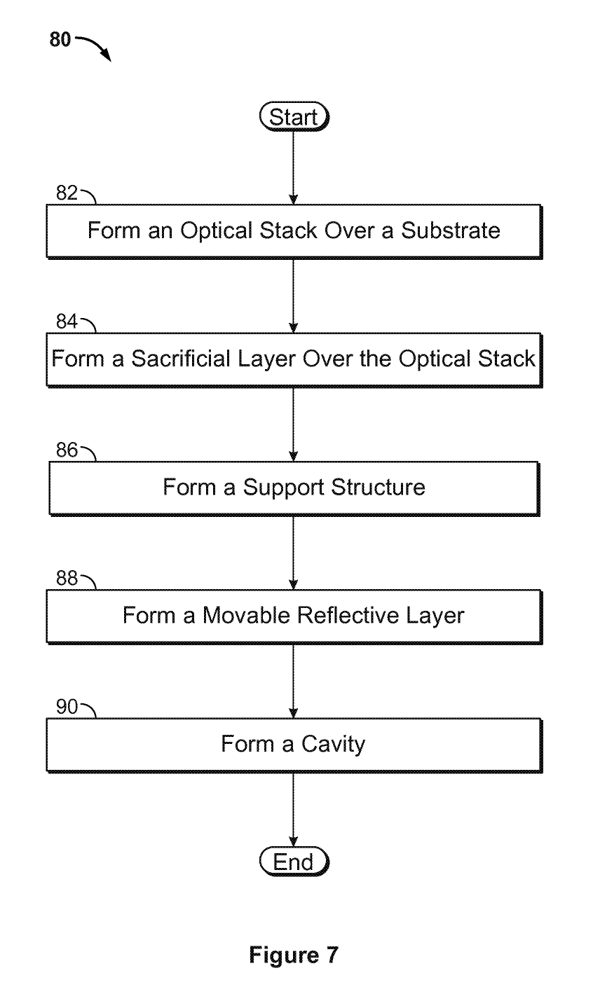

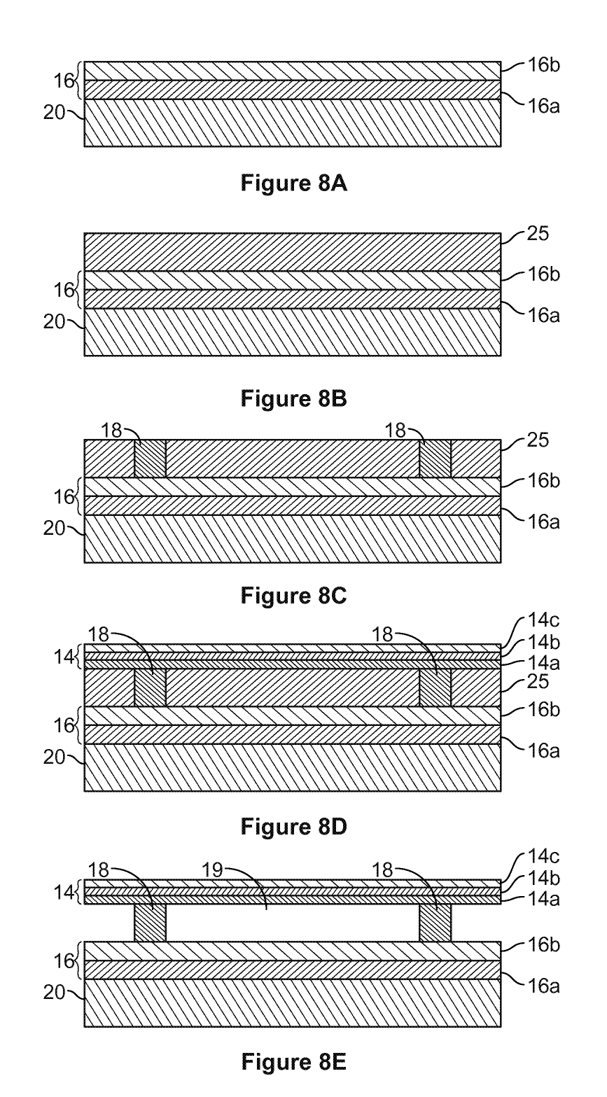

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Implementations described herein relate to substrate packaging of MEMS, including IMODs, and other devices. The through-substrate vias described herein may be implemented for MEMS and non-MEMS devices including on-wafer (or on-panel) devices that are formed prior to die singulation, such as dies embellished with leads or pads for connecting the device to another package, directly to a printed wiring board or flex tape, or for stacked or multi-substrate configurations. While implementations of the methods of fabrication and the resulting through-substrate vias are described chiefly in the context of glass packaging of MEMS and IC devices, the methods and vias are not so limited and may be applied in other contexts that employ a conductive path through an insulating substrate.

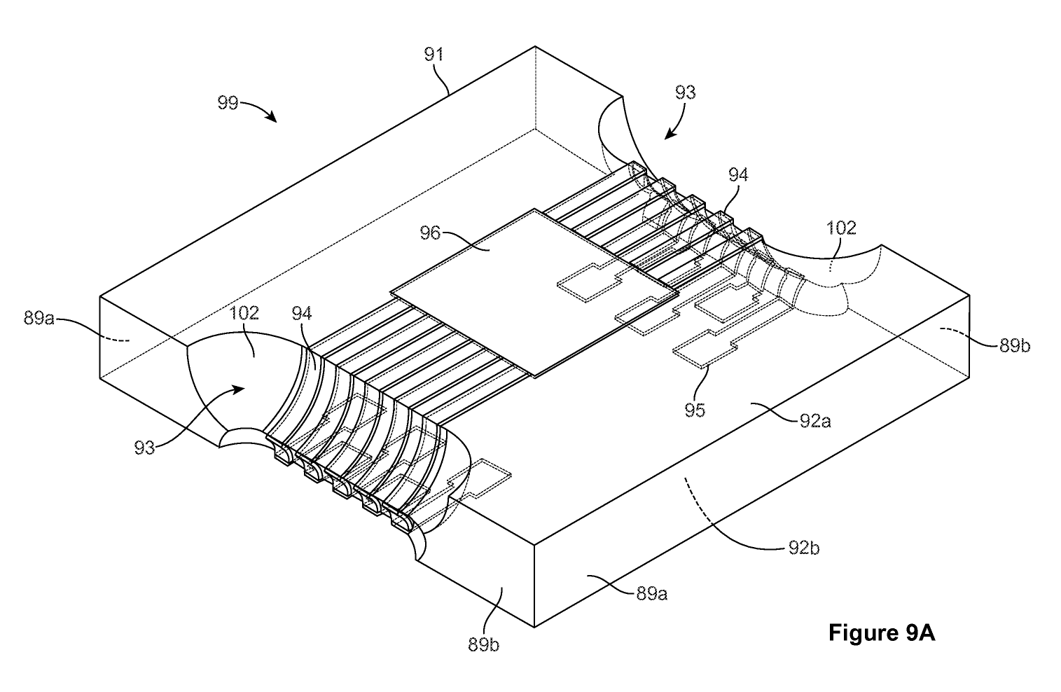

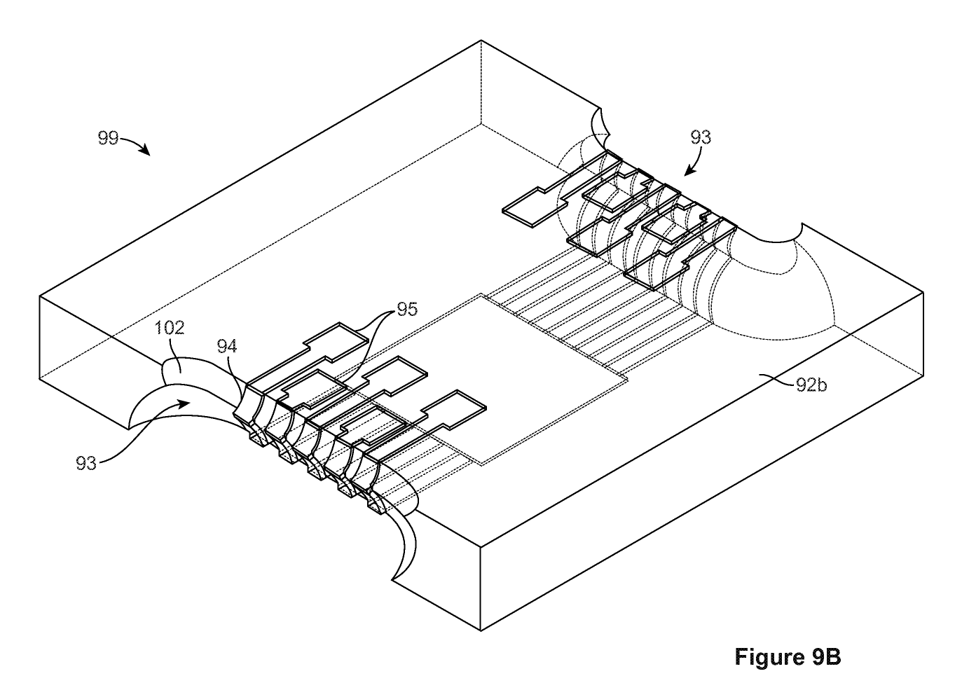

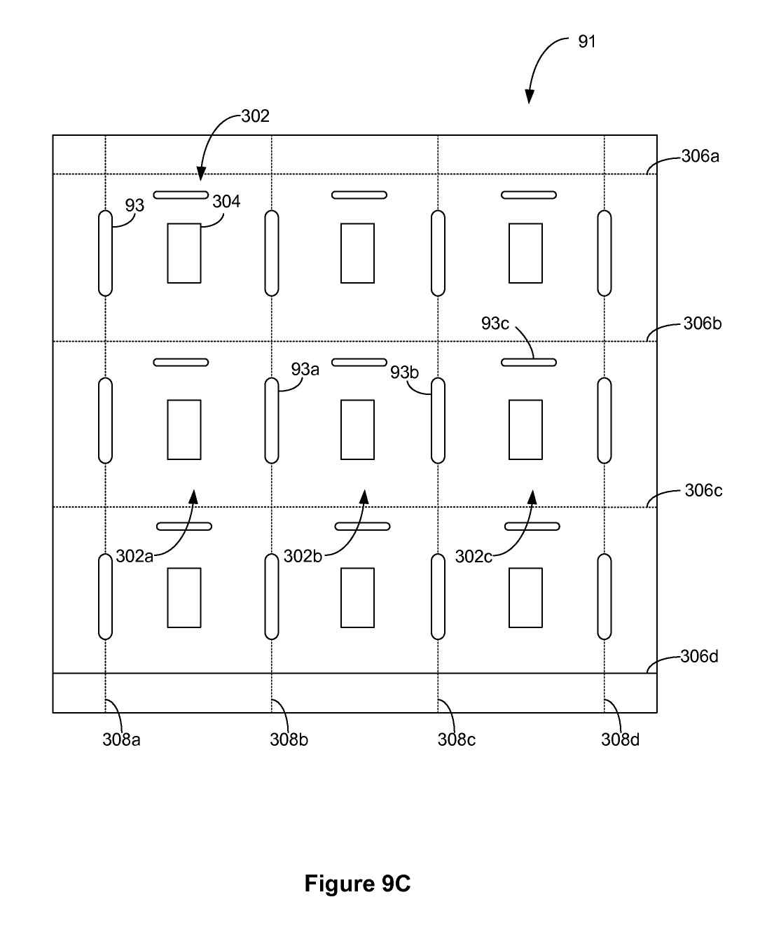

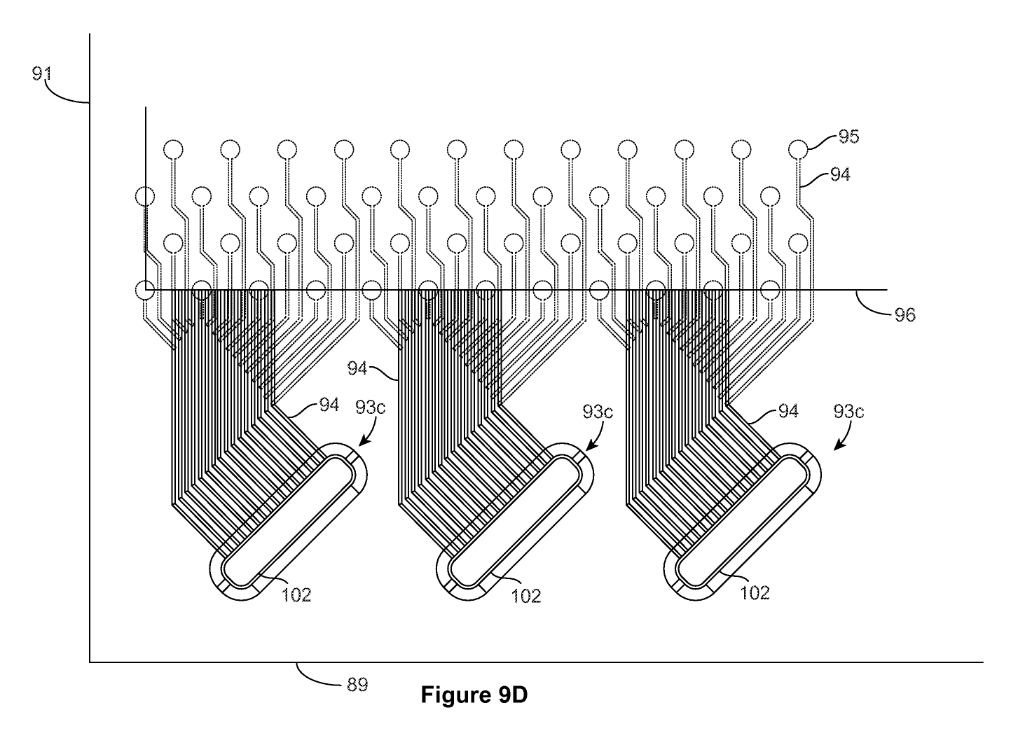

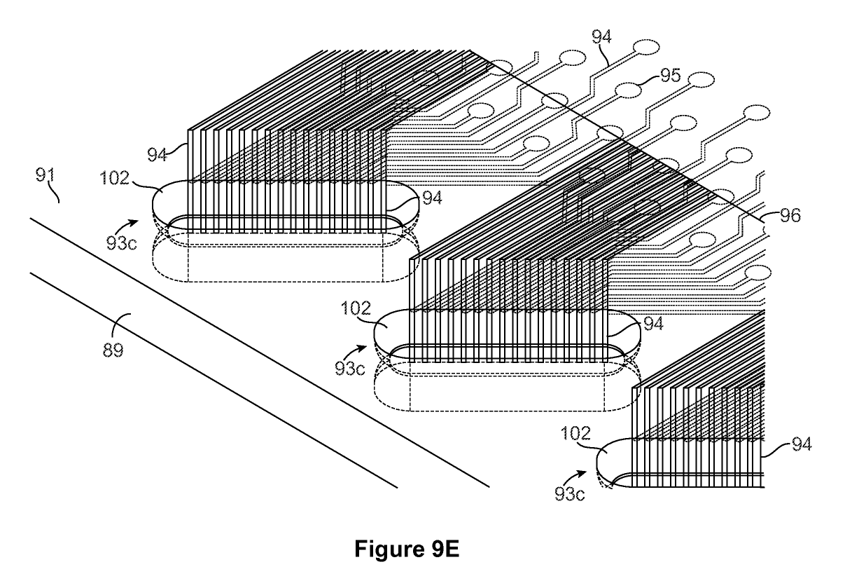

FIGS. 9A and 9B show examples of isometric and bottom views depicting a device including peripheral multi-trace through-glass vias. FIG. 9A shows an example of device 99 including glass substrate 91 with peripheral through-glass vias 93 formed therein. Glass substrate 91 is a generally planar substrate having two major substantially parallel surfaces, top surface 92a and bottom surface 92b. Glass substrate 91 also has two sets of parallel peripheral surfaces, also referred to as side surfaces, peripheral surfaces 89a and peripheral surfaces 89b. Peripheral surfaces 89a and 89b are minor surfaces that are substantially perpendicular to top surface 92a and bottom surface 92b. A MEMS device 96 is attached to or formed on the top surface 92a of glass substrate 91. Although it is depicted as transparent in the associated Figures, glass substrate 91 may be transparent or non-transparent. As illustrated, each peripheral through-glass via has curved sidewalls and includes multiple conductive lines 94, also referred to as traces, that extend between portions of top surface 92a and bottom surface 92b through glass substrate 91. Peripheral through-glass vias 93 are located on the periphery of glass substrate 91, with each recessed from a peripheral surface 89a. Each peripheral through-glass via 93 includes a sidewall 102 and conductive lines 94 extending along sidewall 102. Each conductive line 94 provides a conductive pathway between portions of top surface 92a and bottom surface 92b through glass substrate 91. In the example depicted in FIG. 9A, each conductive line 94 provides a connection from MEMS device 96 to a bond pad 95 on bottom surface 92b. Specifically, each conductive line 94 extends from through-glass via 93 to connect to MEMS device 96 on top surface 92a and extends from through-glass via 93 to connect to bond pad 95 on bottom surface 92b. In the example shown, bond pads 95 allow for connections to a printed circuit board or other substrate or device (not shown). Through-glass vias 93 thus provide direct electrical connection from one or more traces, pads, ICs, MEMS devices, or other components on one side of glass substrate 91 to one or more traces, pads, ICs, MEMS devices or other components on the opposing side. In the example depicted, each through-glass via includes multiple conductive lines 94, though in other implementations, there may be a single conductive pathway. In various implementations, all or most of the via sidewalls may be coated with a conductive material, or a single line may be patterned. In the depicted example, peripheral through-glass vias 93 are on two peripheral, opposite sides of glass substrate 91, though in other implementations they may be included on any number of sides. Also, multiple through-glass vias may be included on any one side.

FIG. 9B shows an example of a bottom view of the device 99 depicted in FIG. 9A. Conductive lines 94 extend from peripheral through-glass vias 93 to bond pads 95. As illustrated, bond pads 95 are arranged in a staggered formation of two rows that allows a greater density of conductive lines 94 in a peripheral through-glass via 93. In alternate implementations, the bond pads are not staggered or are staggered in more than two rows for a higher density. Bond pads 95 may be surface mount device (SMD) pads configured to connect to a printed circuit board (PCB), for example, or may provide an electrical interface to a PCB or other device. In some implementations, bond pads 95 are configured for attachment to “flex tape,” i.e., a tape or other flexible substrate material that supports one or more conductors and that provides electrical connection to one or more external electrical components such as ICs, PCBs and the like.

In some implementations, peripheral through-glass vias facilitate reduced package sizes. FIG. 9C shows an example of a top view of a glass substrate including multiple dies and peripheral and non-peripheral through-glass vias prior to die singulation. Glass substrate 91 includes dies 302, with each die including component 304 and two peripheral through-glass vias 93. Component 304 can be an electromechanical systems device, sensor, circuitry, contact pad, SMD pad, or other electrically active device or conductive material. In some implementations, component 304 includes a wireless communications device. Horizontal dicing streets 306a, 306b, 306c and 306d and vertical dicing streets 308a, 308b, 308c, and 308d are indicated. Dicing streets are lines along which the glass substrate 91 will be diced to singulate dies 302. Peripheral through-glass vias 93 are each centered on one of the vertical dicing streets 308a, 308b, 308c or 308d. Prior to die singulation, each peripheral through-glass via 93 is shared by two adjacent dies 302. For example, peripheral through-glass via 93a is shared by dies 302a and 302b and peripheral through-glass via 93b is shared by dies 302b and 302c. In some implementations, sharing vias facilitates reducing die size. A die can include one or more peripheral through-glass vias on any number of sides according to the desired implementation. In some implementations, a peripheral through-glass via is centered on every other dicing street, such that each die includes one shared through-glass via prior to die singulation. In some implementations, a die can have peripheral through-glass vias on adjacent sides, in addition to or instead of on opposing sides.

In some implementations, non-peripheral through-glass vias are provided alone or in addition to peripheral through-glass vias. One example is illustrated in FIG. 9C, where dies 302 each optionally include non-peripheral vias. For example, via 93c is located in the interior and not on the periphery of die 302c. FIGS. 9D and 9E show examples of top and isometric views depicting a device including non-peripheral multi-trace through-glass vias. In particular, FIGS. 9D and 9E show examples of a close up view of through-glass vias 93c formed in a glass substrate 91. Through-glass vias 93c are located in the interior of glass substrate 91, rather than the periphery. Each through-glass via 93c includes sidewall 102 and conductive traces 94 extending along sidewall 102. Conductive lines 94 extend from a MEMS device 96 on one side of glass substrate 91 to bond pads 95 on the other side of glass substrate 91. The conductive lines 94 are continuous from the MEMS device 96 to the bond pads 95. (A bottomside segment of each conductive line 94 is obscured by a topside segment in FIG. 9D). The shape and orientation of the vias with respect to a peripheral surface can vary according to the desired implementation. In the example of FIGS. 9D and 9E, through-glass vias 93c are slot-shaped with the length of the slot non-parallel to a peripheral surface 89 of glass substrate 91. Conductive lines 94 also are angled to extend from vias 93c to MEMS device 96.

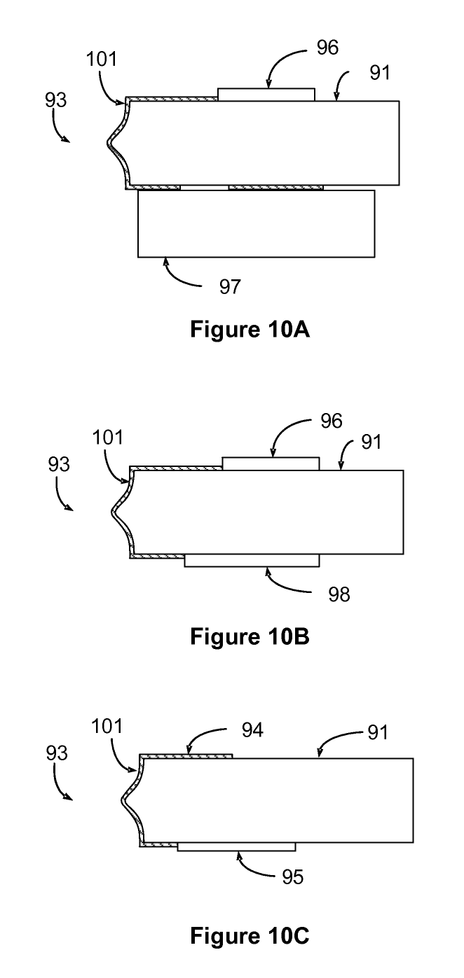

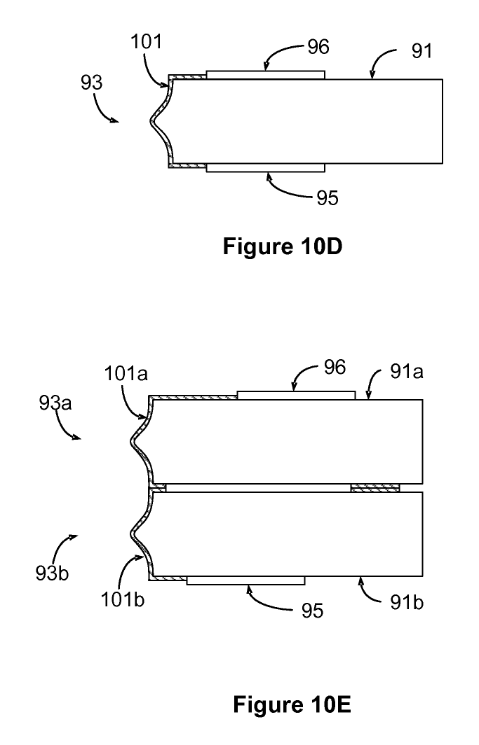

FIGS. 10A-10E show examples of simplified cross-sectional schematic illustrations of glass substrates having peripheral through-glass vias. In the example of FIG. 10A, a peripheral through-glass via 93, including sidewall metallization 101, is provided in a glass substrate 91. In this implementation glass substrate 91 is a MEMS device glass substrate, i.e., a glass substrate on which a MEMS device 96 is formed or otherwise attached. Through-glass via 93 provides an electrical connection between MEMS device 96 on one side of MEMS device glass substrate 91 and a flip-chip bonded integrated circuit 97 on the other side of MEMS device glass substrate 91. Sidewall metallization 101 can be a single patterned conductive line, multiple patterned conductive lines (such as conductive lines 94 depicted in FIG. 9A), or a thin film coating on all or part of the sidewall. In the example of FIG. 10B, a peripheral through-glass via 93 is also provided in a glass substrate 91, which may also be a MEMS device substrate. In this implementation, through-glass via 93 having sidewall metallization 101 in the via 93 connects a MEMS device 96, such as a display, on one side of the MEMS device glass substrate 91 to an electrically active component 98 on the other side. Electrically active component 98 may be an electronic device or component, such as a driver or control circuit or chip, or another MEMS device, such as a MEMS sensor or other MEMS device. Electrically active component 98 may include a wireless communications chip for a cell phone or a wireless data communications chip. In the example of FIG. 10C, the glass substrate 91 is an SMD glass substrate. The peripheral through-glass via 93 is formed in the glass substrate 91 and provides a conductive path between a bond pad 95, illustrated here as an SMD pad, on one side of SMD glass substrate 91 and a conductive line 94 on the other side. In the example of FIG. 10D, a peripheral through-glass via 93 is formed in a MEMS device glass substrate 91 to provide an electrical connection between a MEMS device 96 and a bond pad 95, illustrated here as an SMD pad, on opposite sides of MEMS device glass substrate 91. MEMS device glass substrate 91 may be directly mounted, for example, on a PCB with bond pad 95 providing an electrical interface to the PCB (not shown).

In some implementations, two or more substrates with at least one substrate having a partially or fully thin-film-coated through-glass via are joined together. For example, in FIG. 10E, a peripheral through-glass via 93a, including sidewall metallization 101a, is formed in a MEMS device glass substrate 91a and is connected to another peripheral through-glass via 93b including sidewall metallization 101b that is formed in an SMD glass substrate 91b. MEMS device glass substrate 91a and SMD glass substrate 91b are bonded together, e.g., with a metal or a polymer such as a UV-curable polymer. Peripheral through-glass vias 93a and 93b electrically connect MEMS device 96 fabricated on MEMS device glass substrate 91a to bond pad 95 formed on SMD glass substrate 91b. In certain implementations, one or more contact pads may be formed between peripheral through-glass vias 93a and 93b. While peripheral through-glass vias 93a and 93b are directly aligned in FIG. 10E, in alternate implementations (not shown) the peripheral through-glass vias are not directly aligned, and may be electrically interconnected with conductive traces and contact pads on one or both substrates. In alternate implementations, a peripheral through-glass via is connected to non-peripheral through-glass vias on a second substrate. Also in alternate implementations, the bond pads are configured to connect to a flex tape connector.

While FIGS. 9A-9E and 10A-10E provide examples of implementations of through-glass vias described herein, they are not limited to these implementations, but may be used to provide a conductive path through any glass substrate. According to various implementations, the through-glass vias may be used alone or in connection with contact pads, metal lines or traces, and the like to connect any electrically passive or active element such as a capacitor, inductor, resistor, device, sensor, circuitry, chip, via, bond or contact pad, SMD pad, or conductive material on one side of a glass substrate to any other electrically passive or active element such as a capacitor, inductor, resistor, device, sensor, circuitry, chip, via, bond or contact pad, SMD pad or conductive material on the other side of the glass substrate.

According to various implementations, the glass substrate in which a through-glass via is formed is substantially planar having substantially parallel major surfaces (also referred to as top and bottom surfaces). One having ordinary skill in the art will understand that each surface may also include various recessed or raised features to accommodate, for example, a MEMS component, an integrated circuit, or other device. According to various implementations, the thickness of the glass substrate is typically between about 50 and 700 microns. The substrate thickness may vary according to implementation. For example, in certain implementations in which the glass substrate is a MEMS device substrate that is to be further packaged, the thickness may be between about 50 and 300 microns, such as 100 microns or 300 microns. Substrates that include SMD pads and are configured to mount onto a PCB may have thicknesses of at least about 300 microns, such as between about 300 and 500 microns. Configurations that include one or more glass substrates or panels may have thicknesses of 700 microns or more.

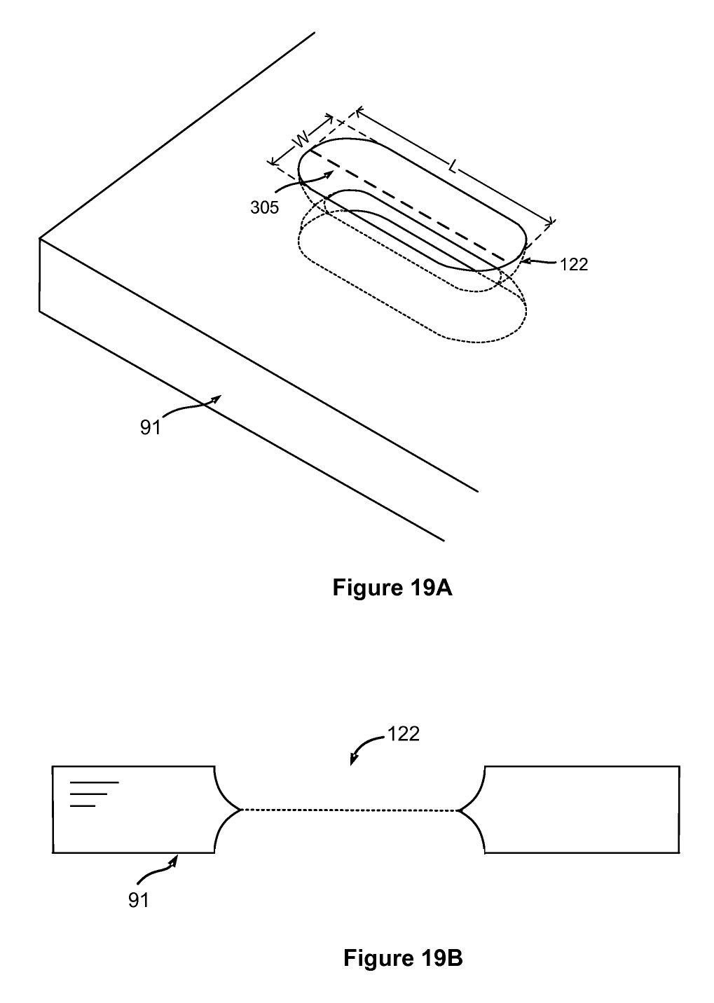

The number, shape and placement of the through-glass vias may vary according to implementation. For example, one or more peripheral vias may be located on the periphery of one, two, three or more sides of a glass substrate. In FIGS. 9A-9E, the via openings are elongated with the via opening shape characterized as a slot shape or a half-slot shape, with the half-slot shape referring in some implementations to the shape of a slot-shaped via that has been diced into two separated portions. A slot-shaped via opening may be characterized as an elongated rectangle having rounded corners, with a longer dimension, length L, and a shorter dimension, width W. An example of a slot-shaped via is depicted in FIG. 19A. In alternative implementations, via openings may be otherwise shaped, including semi-circular. The via openings may also be oval-shaped, half-oval shaped, circle-shaped, half-circle shaped, rectangular-shaped, square-shaped, half-square shaped, square-shaped with rounded corners, half-square shaped with rounded corners, etc. In some implementations, multiple vias are arranged in arrays. In some implementations, via openings have rounded edges with no sharp corners.

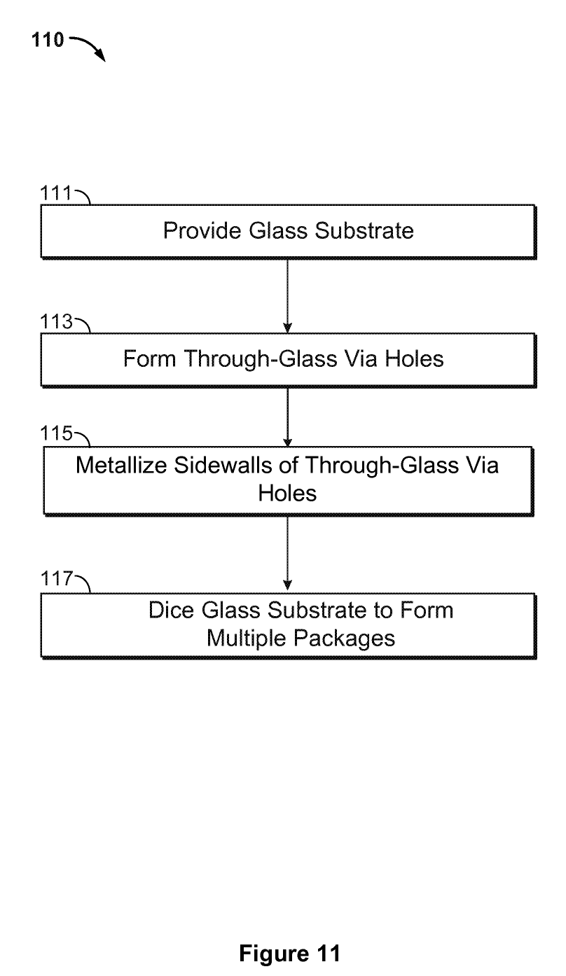

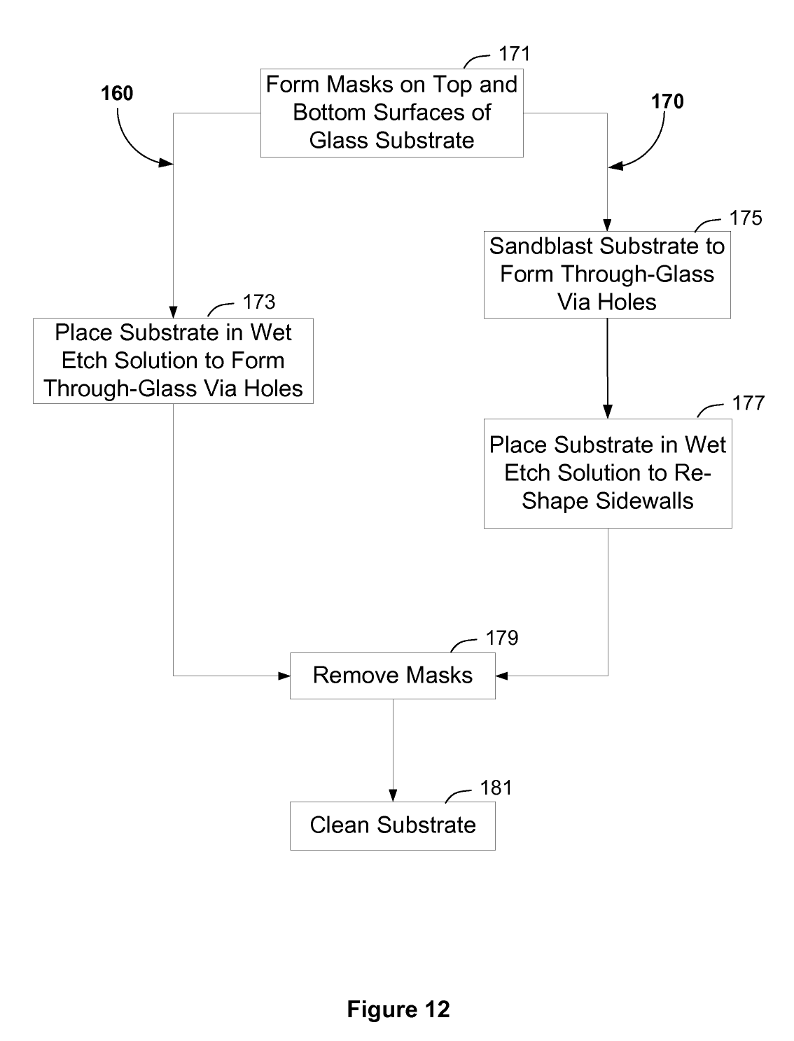

FIG. 11 shows an example of a flow diagram illustrating a process for forming a peripheral through-glass via. The process 110 starts at block 111 in which a glass substrate is provided. The description of the process 110 (as well as processes 160 and 170 of FIG. 12) that follows will focus on implementations with a glass substrate, but it is understood that other substrates, such as non-glass insulating substrates, may also be used. Thicknesses of the glass substrate according to various implementations are described above. The substrates may be any appropriate area. In some implementations, a glass substrate (sometimes referred to as a glass plate or panel) having an area on the order of four square meters or greater is provided with a thickness, for example, of 0.3, 0.5, or 0.7 millimeters. Alternatively, round substrates with diameters of 100 millimeters, 150 millimeters, or other diameters may be provided. In some other implementations, square or rectangular sub-panels cut from a larger panel of glass may be provided. The glass substrate may be or include, for example, a borosilicate glass, a soda lime glass, quartz, Pyrex, or other suitable glass material. The glass substrate may be provided with or without MEMS devices and/or other components (metal traces, contact pads, circuitry, etc.) already fabricated on one or both sides of the substrate. In some implementations, the MEMS devices and/or other package components are formed after formation of the through-glass vias, or at any appropriate point during formation of the through-glass vias.

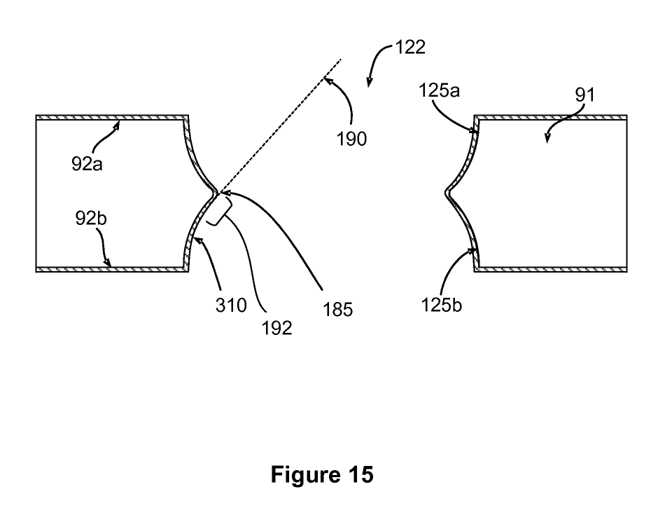

The process 110 continues at block 113 with formation of through-glass via holes. Through-glass via holes can be formed by one or more operations including wet etching, dry etching and sandblasting (also known as powder blasting). In some implementations, a double-sided process is performed to form through-glass via holes in the glass substrate. A double-sided process of forming a through-glass via hole involves forming two holes that are partially etched, that is not completely etched to opposite side of the glass substrate, one on each side of the glass substrate. At some point during or after formation of these two partially through holes, they are joined by etching or otherwise removing glass material between them. The two partially through holes are aligned such that when joined, the aligned through holes overlap near a mid-section of the glass substrate, forming the through-glass via hole. Double-sided processes can involve one or more of simultaneous wet or dry etching of aligned partially through holes, sequential wet or dry etching of aligned partially through holes, and simultaneous or sequential sandblasting of aligned partially through holes according to the desired implementation. In some implementations, a double-sided process involves a double-sided sandblasting process followed by a wet etching process to further shape and contour the via holes. Further details and examples of double-sided processes are described below with respect to FIG. 12. In some implementations, the via holes are shaped to facilitate subsequent metallization of the via hole sidewalls from one or both sides of the glass substrate. This is discussed further below with respect to FIGS. 15-17.

After forming the through-glass via holes, the process 110 continues at block 115 with metallization of the sidewalls of the through-glass via holes. Metallizing the sidewalls involves coating all or a portion of the sidewalls with a continuous conductive film. In some implementations, multiple conductive lines are formed. The multiple conductive lines can be electrically isolated from each other, such that each metal line provides a distinct conductive pathway through the glass substrate. In some implementations, a single conductive line or other pathway is formed. If multiple lines are formed, the pitch can vary according to the desired implementation. (As used herein, the pitch of spaced apart lines refers to the width of one line plus the width of one spacing.) For example, a pitch of the sidewall lines can be anywhere from less than about 10 microns to greater than about 300 microns according to the desired implementation. In various implementations, the linewidths can vary, for example, from less than 20 microns wide to over 100 microns wide. In various implementations, spaces between adjacent conductive lines can vary from less than 20 microns to 500 microns or larger.

In some implementations, sidewall metallization includes one or more of a sputter deposition process or other physical vapor deposition (PVD) process, a chemical vapor deposition (CVD) process, an atomic layer deposition (ALD) process, an evaporation process, an electroless plating process, an electroplating process, a jetting process and a spraying process. In some implementations, sidewall metallization includes patterning using resists and/or etching.

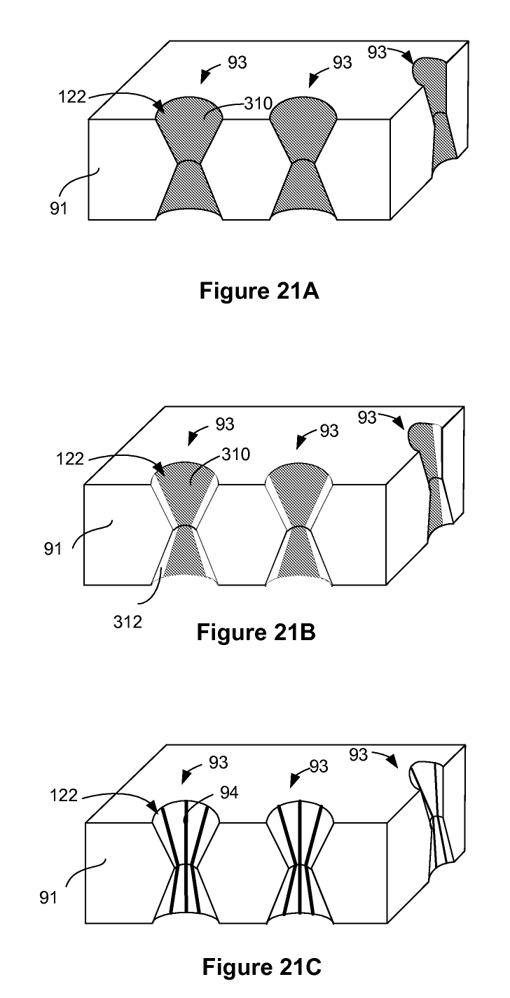

In some implementations, block 115 is a one-sided deposition process. For example, in some implementations, block 115 is a one-sided sputtering process in which a target positioned above one surface, or the other, of a substrate including a through-glass via hole is sputtered to deposit the target material on the surface of the substrate and on the sidewalls of both the upper and lower via holes. Conductive thin film material enters the through-glass via hole only through the via opening on that surface. In some other implementations, block 115 is a two-sided process in which material is deposited in a through-glass via hole through each via opening, either simultaneously or sequentially. In some implementations, sidewall metallization can include one or more techniques such as jetting, dispensing, spraying, and the use of electrophoretic resists to form patterned metal lines. These can be one-sided or two-sided processes. As described further below, the technique used in block 115 can vary according to the pitch of conductive lines in a desired implementation. Further details and examples of sidewall metallization processes are described below with respect to FIGS. 21A-21C.

In addition to metallizing the inside surface of a via hole, metal or other conductive material may be formed on one or both of the top and bottom surfaces of the glass substrate, in at least a portion of the area surrounding the via opening on that surface. The films formed on the top and/or bottom surface may be patterned and etched to form electrical traces and/or contact pads that are electrically connected to the fully or partly metallized via hole. The patterning and etching may be performed before, after or during block 115. For example, in some implementations, a deposition mask is formed on a top and/or bottom surface prior to deposition of a thin film on the sidewalls so that the films are deposited in the desired pattern. The sidewall metallization also may be deposited to connect to existing metal traces and other features on the top and/or bottom surfaces.

In some implementations, after sidewall metallization, the via holes are filled or partially filled by a metal, other conductive material, or a non-conductive material. In other implementations, the interior of the via hole is left unfilled. If used, a filler material can be a metal, a metal paste, a solder, a solder paste, one or more solder balls, a glass-metal material, a polymer-metal material, a conductive polymer, a non-conductive polymer, an electrically conductive material, a non-conductive material, a thermally conductive material, a heat sink material, or a combination thereof. In some implementations, the filler material reduces the stress on a deposited thin film and/or plated layer. In some other implementations, the filler material seals the via holes to prevent transfer of liquids or gases through the via holes. The filler material may serve as a thermally conductive path to transfer heat from devices mounted on one side of the glass substrate to the other. According to various implementations, the via holes may be filled or partially filled using a process such as plating, a squeegee-based process, dispensing or direct writing a filler material, screen printing, spray coating, or other appropriate via fill process. In implementations in which the thin films are deposited on the top and/or bottom surfaces of the glass substrate, the thin films may be patterned and etched prior to or after the via holes are filled.

Prior to dicing the glass substrate to form individual dies, the glass substrate may be further processed by additional deposition, patterning and etching sequences to form electrical connections, devices, or other features. Various other operations may take place, including joining the glass substrate to one or more additional substrates or components. For example, a cover glass substrate can be joined to a device substrate to encapsulate devices on the device substrate.

The process 110 continues at block 117 with dicing of the glass substrate to form multiple packages. Dicing can include forming dicing streets along which the glass substrate will be cut and cutting along the dicing streets with a dicing saw or laser. As described above with respect to FIG. 9C, at least some of the dicing streets go through a through-glass via hole. In some implementations, a dicing street includes a center line of one or more through-glass via holes.

FIG. 12 shows an example of a flow diagram illustrating processes for forming through-glass via holes. The flow diagram depicts examples of alternative double-sided methods 160 and 170 of forming through-glass via holes according to various implementations. Both methods begin with forming masks on the top and bottom surfaces of the glass substrate in block 171. The glass substrate may be provided with or without electromechanical systems devices and/or other components already fabricated on one or both sides of the substrate. In some implementations, electromechanical systems and other devices may be formed during or after formation of the through-glass vias. Forming a mask generally involves applying a photo-sensitive layer on the glass substrate, exposing a pattern lithographically into the photo-sensitive layer, and then developing the photo-sensitive layer. Alternatively, an etch-resistant layer deposited on the glass substrate can be patterned and etched, and then serve as an etch mask. Stencils or other masking techniques may also be used as masks for wet, dry, or sandblasting operations. The masks are formed to correspond to the placement and size of the via holes. In some implementations, the masks on the top and bottom surfaces are mirror images, with mask openings on either side of the substrate aligned to allow formation of aligned partially through via holes and the subsequent through-glass via hole. To form a through-glass via hole having differently sized via openings on the top and bottom side of the substrate, differently sized, yet aligned mask openings in the masks may be formed.

For isotropic removal processes such as isotropic wet chemical etches, the mask openings can be substantially smaller than the eventual desired via opening size. For example, for a circular via opening having a 100 micron diameter, the mask opening may be as small as about 1-20 microns, such as 10 microns; for a circular via opening having a 500 micron diameter, the mask opening may be about 10-100 microns, etc. For anisotropic removal processes such as sandblasting or dry etching, the mask opening is generally on the size of the eventual desired via opening size. In some implementations, the eventual via opening size is on the order of the substrate thickness.

The processes also allow some tolerance in the alignment. In some implementations, because the via openings are fairly large with diameters or lengths on the order of hundreds of microns, corresponding mask openings may be aligned within tens of microns or less. In some other implementations, one or both of the top and bottom masks also may have non-corresponding mask openings to allow formation of recessed features other than the double-sided via holes in addition to the double-sided holes.

The mask material may be selected depending on the subsequent glass removal operation, i.e., etching or sandblasting. For wet etching, mask materials may include photoresist, deposited layers of polysilicon or silicon nitride, silicon carbide, or thin metal layers of chrome, chrome and gold, or other etch-resistant material. For sandblasting, mask materials include photoresist, a laminated dry-resist film, a compliant polymer, a silicone rubber, a metal mask, or a metal or polymeric screen.

After the top and bottom surfaces are appropriately masked, the through-glass via holes are formed. In process 160, this involves placing the substrate in a wet etch solution as shown in block 173. Wet etch solutions include hydrogen fluoride based solutions, e.g., concentrated hydrofluoric acid (HF), diluted HF (HF:H₂O), buffered HF (HF:NH₄F:H₂O), or other suitable etchant with reasonably high etch rate of the glass substrate and high etch selectivity for glass compared to the masking material. The etchant also may be applied by spraying, puddling, or other known techniques. The wet etch sequence may be performed consecutively on one side and then the other, or on both sides simultaneously. In process 160, the through-glass via holes are formed in the glass entirely by wet etching, without a previous sandblast or other post-masking glass removal operation. This can form a partially through via hole with curved sidewalls having a generally constant radius of curvature. The process continues at least until aligned via holes formed in the top and bottom surfaces break through to create a through-glass via hole. In some implementations in which the via opening is circular and the mask opening is small, the resulting through-glass via hole may be characterized as having two intersecting hemispherically shaped via holes. Regardless of the via opening shape, each of the aligned holes of a contoured through-glass via hole has sidewalls with a concave curvature extending from the planar glass substrate surface to a point in the interior of the glass at which the aligned holes meet. For example, a suitably contoured sidewall can allow line-of-sight sputter deposition of a thin metal layer through the via to provide continuous electrical connectivity through the via hole, even with a single-sided deposition.

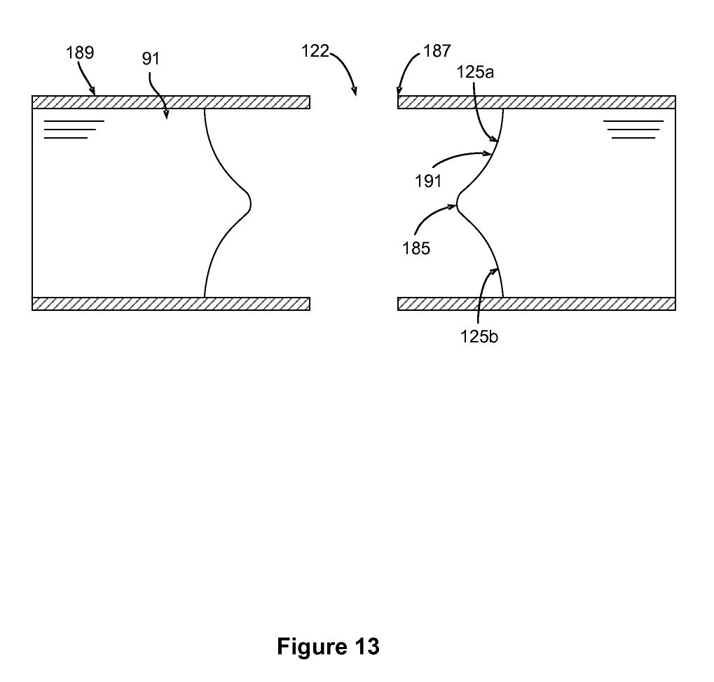

FIG. 13 shows an example of a cross-sectional schematic illustration of a through-glass via hole formed by double-sided wet etching. Through-glass via hole 122 includes aligned partially through via holes 125a and 125b that intersect at a point in the interior of a glass substrate 91. The intersection 185 of via holes 125a and 125b is indicated, and is shown with a small yet finite radius of curvature. A mask opening 187 in the top surface of glass substrate 91 is defined by mask 189, with a similar mask opening in the bottom surface. Via hole 125a includes a sidewall 191 concavely curved from the top surface of glass substrate 91 to intersection 185. The radius of this curvature is substantially constant along sidewall 191. Via hole 125b similarly has sidewalls concavely curved from the bottom surface of glass substrate 91 to intersection 185. The dimension (such as diameter) at the intersection 185 of the upper and lower via holes 125a and 125b near the midplane of glass substrate 91 is less than a dimension (such as diameter) of the via openings at the top and bottom surfaces.

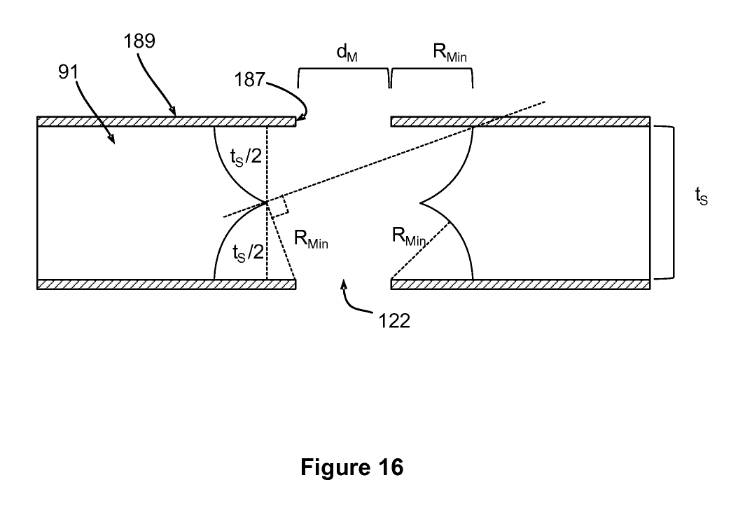

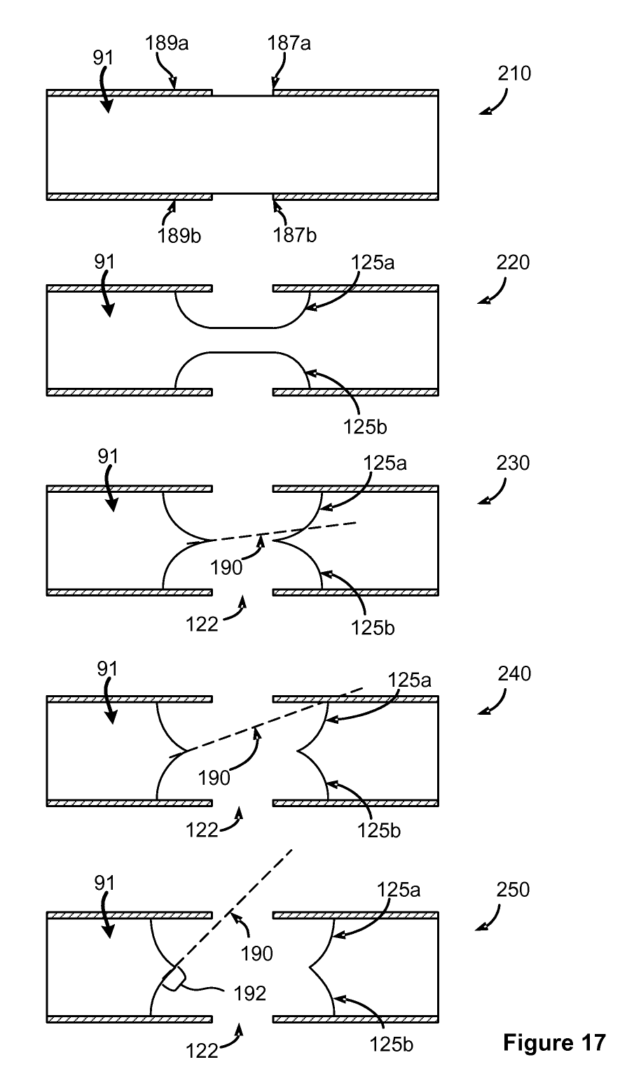

Returning to FIG. 12, according to various implementations, wet etching block 173 is performed to contour a through-glass via hole so as to facilitate subsequent deposition of a continuously conductive thin film. For example, in some implementations, the wet etching operation is performed such that the intersection of the aligned via holes is smooth and rounded with no sharp edges, having a small yet tailored radius of curvature. The radius of curvature at the intersection can be affected, for example, by the intensity or lack of etchant agitation during the etching operation. In some implementations, the via hole is contoured to permit deposition of a continuous thin film from only a single side. A smooth, continuously curved profile allows uniform, non-shadowed coverage of the exposed sidewalls with a deposited thin film. The wet etching operation is discussed further below with respect to FIGS. 16 and 17.

As described above, wet etching block 173 involves simultaneous double-sided etching. In alternate implementations, the top and bottom sides of the glass substrate may be etched sequentially. Once the through-glass via is etched, the masks are removed from both sides of the glass substrate as shown in block 179. The substrate is then cleaned in a block 181 to prepare the substrate for deposition of continuous thin films in the through-glass via holes and other subsequent processing.

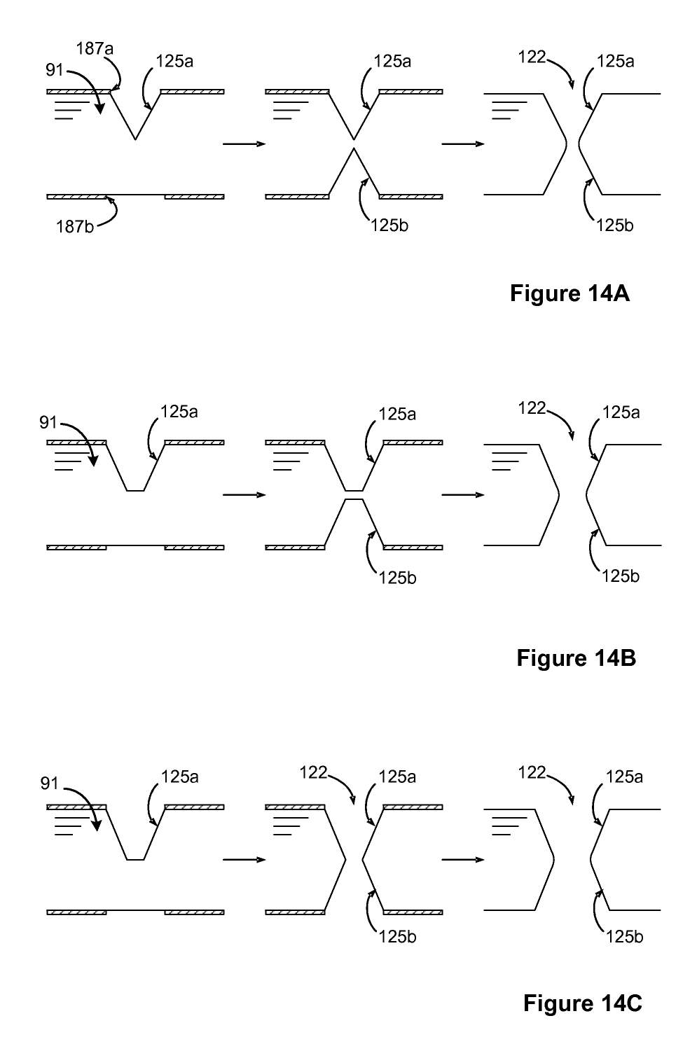

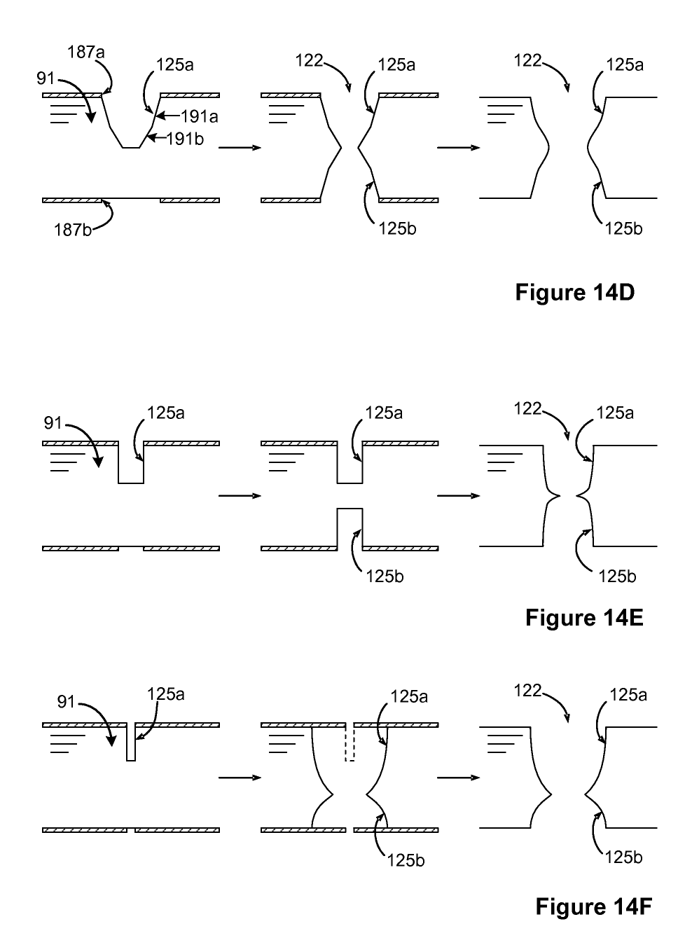

Process 170 describes operations in alternative implementations of forming through-glass via holes. After the top and bottom surfaces of a glass substrate are masked in block 171, the substrate is sandblasted to form through-glass via holes in a block 175. The through-glass via holes may be formed by sandblasting each side of the substrate through, for example, aligned stencil patterns on one or both sides of the substrate. Masking and sandblasting each side may be performed simultaneously or consecutively. FIGS. 14A-14F show examples of cross-sectional schematic illustrations of various stages of sandblasting methods for forming through-glass via holes.

In some implementations, the sandblasting operation proceeds at least until aligned via holes formed in the top and bottom surfaces break through to create through-glass via holes. In some implementations in which the sandblasting operation is succeeded by a wet etch, the double-sided sandblasting of the aligned via holes may stop before breakthrough, with breakthrough occurring during the wet etch. For example, sandblasting may be performed through small-diameter mask openings that self-limit the depth of sandblasting from each side prior to wet etching, as described below with respect to FIG. 14A. Alternatively, sandblasting can be performed for a pre-specified or pre-determined time and stopped prior to breakthrough, with breakthrough occurring during the wet etch as described below with respect to FIG. 14B. In another implementation, double-sided sandblasting can be performed past breakthrough to form a through-glass via hole, followed by a wet etch to further contour the through-glass via hole, as described below with respect to FIG. 14C. In some implementations, the sandblasting operation forms via holes with tapered, substantially linear sidewalls. In some implementations, forming curved rather than straight tapered sidewalls involves using a higher pressure sandblast to form the top of each via hole with a steeper taper, followed by a lower pressure sandblast to form the bottom of each hole with a less steep taper as the hole nears the mid-plane of the glass substrate. In these implementations, sandblast pressure may be varied in a step-wise or continuous manner. An example of a step-wise sandblasting technique is described below with respect to FIG. 14D.

After double-sided sandblasting, the resulting through-glass via hole is exposed to a wet etchant in block 177. In some implementations, the wet etchant serves only to re-texture the sidewalls, smoothing them for subsequent depositions. In some other implementations, the wet etch is allowed to continue to contour the through-glass via. One example is depicted in FIG. 14A, which shows an example of a cross-section of a glass substrate 91 with a through-glass via hole 122 formed by sequential double-sided sandblasting with self-limiting partially through via holes. In the depicted implementation, three stages of forming a through-glass via hole 122 are shown. Two aligned via holes 125a and 125b are sequentially formed by sandblasting glass substrate 91 through mask openings 187a and 187b. After sandblasting, the via holes 125a and 125b are tapered with substantially straight sidewalls. Also after sandblasting the aligned via holes 125a and 125b are not connected, though in alternate implementations they may be. A wet etch can then be performed and allowed to proceed for a length of time sufficient to break through and form a through-glass via hole 122 with contoured sidewalls. The contoured sidewalls facilitate improved thin film deposition over constantly tapered sidewalls in some implementations, such as when a direct line-of-sight region is formed near the intersection of via holes 125a and 125b. The wet etchant may be used to remove unwanted damage to the substrate sidewalls from the sandblasting, although it also can be applied in a manner sufficient to avoid shadowing effects with subsequently deposited thin films.

In another implementation, FIG. 14B shows a glass substrate 91 that is masked and sandblasted to form upper via hole 125a, then masked and sandblasted from the opposite side to form lower via hole 125b without breaking through. Upper and lower via holes 125a and 125b can have substantially flat bottom surfaces. The upper and lower via holes can have substantially flat bottom surfaces except near the sidewalls if, for example, the via hole openings are wide enough that the abrasion rate of these surfaces is uniform. After a wet-etch operation, via holes 125a and 125b are connected to form a through-glass via hole 122. In another implementation, a glass substrate 91 is masked and sandblasted on a first side to form upper via hole 125a, then masked and sandblasted on the other side to form a lower via hole 125b of sufficient depth to break through glass substrate 91, as shown in FIG. 14C. A wet etch operation further contours the sidewalls of via holes 125a and 125b to form through-glass via hole 122.

In an example of a step-wise sandblasting method, FIG. 14D shows a glass substrate 91 with upper and lower masks such as a stencil or a screen having mask openings 187a and 187b through which sandblasting is performed in a step-wise manner. Upper via hole 125a is first formed, with its sidewall having two sections 191a and 191b having substantially straight sidewalls of different slopes formed by two sandblasting steps having different pressures. In alternate implementations, more than two steps may be performed. After an upper via hole 125a is formed, a lower via hole 125b is similarly formed, resulting in a through-glass via hole 122. A wet-etch operation may optionally follow to further contour the through-glass via hole 122.

Returning to FIG. 12, after wet etch block 177 is performed, method 170 ends similarly to method 160, such as by removing the masks from both sides of the glass substrate in block 179 and cleaning the substrate in block 181. In alternate implementations, the wet etch or sandblast operations may be replaced by a dry etch or a combination of dry etching and wet etching. Dry etching involves exposing the masked substrate to a plasma, such as, a fluorine-containing plasma. The plasma may be direct (in situ) or remote. Examples of plasmas that may be used include inductively-coupled or capacitively-coupled RF plasmas and microwave plasmas. FIGS. 14E and 14F show examples of cross-sectional schematic illustrations of various stages of dry etch methods of forming through-glass via holes. In one example, FIG. 14E shows dry-etched glass substrate 91 with partially through via holes 125a and 125b, which have generally rectangular cross-sectional profiles. The partially through via holes 125a and 125b are subsequently wet etched to form through-glass via hole 122. In the example depicted in FIG. 14F, a dry-etched glass substrate 91 with an upper via hole 125a on one side can be immersed in a wet etchant to enlarge via hole 125a and simultaneously form lower via hole 125b, which after sufficient etching time merge to form a through-glass via hole 122. In this example, upper via hole 125a and lower via hole 125b intersect at a point other than the midpoint. In some implementations, aligned via holes intersect at a point between 50% and 90% of the height of the substrate as measured from either a top or bottom surface of the substrate. Note also that with this process, less time may be used for the wet etch operation, and the exposed area used for the dry-etch operation is reduced or minimal. In another variant (not shown), dry etching can form a small-diameter via hole from one side of a glass substrate and wet etching can form a hemispherically shaped via hole from the other side to connect the two via holes, so that the area consumed by the via hole opening on the dry-etched side is minimized.

In some implementations, the through-glass via hole is contoured, i.e., shaped and sized, to allow sidewall metallization that is continuous through the hole. The through-glass via hole may be contoured to allow single-sided deposition of a thin film that is continuous through the hole. As described above, a through-glass via hole includes two aligned via holes formed in opposite sides of the glass substrate. In some implementations, the through-glass via hole is contoured such that a tangent line extending from a curved surface on one or the other side of the intersection, yet adjacent the intersection, of both partially through via holes extends through the via opening of the opposite hole. FIG. 15 shows an example of a cross-sectional schematic illustration of a metallized contoured through-glass via hole. As depicted in FIG. 15, through-glass via hole 122 includes aligned hemispherically shaped via holes 125a and 125b that meet at intersection 185, where aligned via hole 125a is formed in top surface 92a and aligned via hole 125b is formed in bottom surface 92b of glass substrate 91. A tangent line 190 that is tangent to a sidewall of aligned via hole 125b near intersection 185 is depicted. Region 192, which extends from intersection 185 to a point along the sidewall surface of via hole 125b, is in some implementations the most challenging region to access from a topside deposition source. However, because tangent line 190 extends through the via opening of via hole 125a in top surface 92a, region 192 is a direct line-of-sight region for an overhead sputtering target or other deposition source (not shown); accordingly region 192 and all other sidewall surfaces of via holes 125a and 125b are accessible for topside thin-film deposition with clear line-of-sight exposure. As a result, topside thin-film deposition by sputtering, plasma deposition, or other suitable deposition technique results in deposition of a continuous thin film through through-glass via hole 122. Increasing the tangent line 190 angle can improve continuity of subsequently deposited thin films, although excessively large via holes can be more difficult to fill and can make the glass substrate 91 fragile.

Through-glass via holes contoured as described in FIG. 15 also may be coated with a continuous thin film using double-sided thin film deposition techniques, such as chemical vapor deposition or low-pressure chemical vapor deposition. Each half of the through-glass via hole can be accessible to deposition from both sides of the glass substrate, resulting in improved deposition as compared to single-sided deposition.

In some implementations, a through-glass via hole contoured as described above with reference to FIG. 15 is formed via a double-sided isotropic wet etch. The etch is allowed to proceed until the etch radius, R, i.e., the distance that the isotropic etch proceeds from the mask opening in any direction, is at least the minimum etch radius, R_{Min}. R_{Min} is the minimum etch radius that provides a via hole contoured such that a tangent line extending from a curved surface on one or the other side of the intersection, yet adjacent the intersection, of both partially through via holes extends through the via opening of the opposite hole as described above. In some implementations, the minimum etch radius is given by Equation 1:

R_{Min}=(√2)(t_{S}/2)/(1+((d_{M}+R_{Min})/R_{Min})(1−(t_{S}/2R_{Min})²)^{1/2})^{1/2} (Equation 1)

with d_{M} being the mask opening dimension and t_{S} the substrate thickness. For example, d_{M} represents the mask opening diameter for circular vias, and the smallest mask opening dimension (such as the width) for slot-shaped mask openings. FIG. 16 shows an example of a cross-sectional schematic illustration of certain etch parameters of a through-glass via hole. In the example shown in FIG. 16, the etch radius is equal to the minimum etch radius, which satisfies Equation 1. Through-glass via hole 122 in glass substrate 91 and mask 189 are depicted. Mask 189 allows an etchant to selectively contact the top surface of glass substrate 91 in the area exposed by mask opening 187. Mask opening 187 may be a circle, a slot, a rectangle or other shape. For a circular mask opening, d_{M} is the diameter of the mask feature. For a non-circular mask opening, d_{M} is the smaller dimension, such as the width of a slot-shaped mask opening. Equation 1 assumes (i) uniform double-sided isotropic etching with no etch acceleration under the mask, (ii) that a similar mask and mask opening feature are aligned on the opposite side of glass substrate 91, and (iii) that the masks are removed prior to thin-film deposition. Examples of minimum etch radii for various mask opening dimensions and substrate thicknesses are given in Tables 1 and 2 for circular and slot vias, respectively. The resulting through-glass via sizes at the top and bottom surfaces and at an intersection of the aligned via holes for a uniform double-sided isotropic wet etch under the above-stated assumptions governing Equation 1 are also given.

TABLE 1
Minimum Etch Radii for Wet-Etched Circular Vias

| | Substrate Thickness (μm) | | | | | |
|---|---|---|---|---|---|---|
| | 100 | | 300 | | 500 | |
| Mask Opening (diameter, μm) | 10 | 20 | 10 | 50 | 10 | 100 |
| Minimum Etch Radius (μm) | 56.7 | 55.8 | 172.1 | 168.2 | 287.6 | 278.8 |
| Minimum Etch Radius | 1.134 | 1.116 | 1.147 | 1.122 | 1.150 | 1.115 |
| (Normalized to ½ tₛ) | | | | | | |
| Diameter - Upper Surface (μm) | 123.4 | 131.6 | 354.2 | 386.5 | 585.2 | 657.7 |
| Diameter - Mid Surface (μm) | 63.5 | 69.6 | 178.8 | 202.4 | 294.3 | 347.0 |
| Diameter - Lower Surface (μm) | 123.4 | 131.6 | 354.2 | 386.5 | 585.2 | 657.7 |

TABLE 2
Minimum Etch Radii for Wet-Etched Slot Vias

| | Substrate Thickness (μm) | | | |
|---|---|---|---|---|
| | 50 | 100 | 300 | 500 |
| Mask Opening (w × l, μm) | 10 × 300 | 10 × 300 | 10 × 300 | 10 × 300 |
| Minimum Etch Radius | 27.9 | 56.7 | 172.1 | 287.6 |
| (μm) | | | | |
| Minimum Etch Radius | 1.115 | 1.134 | 1.147 | 1.150 |
| (Normalized to ½ tₛ) | | | | |
| Via Size - Upper Surface | 66 × 356 | 123 × 413 | 354 × 644 | 585 × 875 |
| (μm) | | | | |
| Via Size - Mid Surface | 35 × 325 | 64 × 354 | 179 × 469 | 294 × 584 |
| (μm) | | | | |
| Via Size - Lower Surface | 66 × 356 | 123 × 413 | 354 × 644 | 585 × 875 |
| (μm) | | | | |

While Tables 1 and 2 provide minimum etch radii for examples of differently sized circular and slot-shaped vias, Equation 1 also may be solved by an iterative or other technique to determine the minimum etch radius for a given substrate thickness and mask opening size. In some implementations, the etch radius, R, is some factor above the minimum, such as 1.1-1.4 R_{Min}, to further improve thin film deposition, resulting in a via opening with a dimension on the order of 1.1-1.5 times the thickness of the glass substrate. An overetch ratio of 10-15% is generally desirable to enable electrical continuity of subsequently deposited thin metal films while keeping the resulting diameter of the via hole small. Robust etch sequences can handle overetch ratios of 40% or higher.

FIG. 17 shows an example of cross-sectional schematic illustrations of a glass substrate at various stages of simultaneous etching of aligned via holes to form a through-glass via hole. As depicted in FIG. 17, simultaneous etching of aligned via holes 125a and 125b in glass substrate 91 using masks 189a and 189b with aligned mask openings 187a and 187b forms a through-glass via hole 122. First, at 210, glass substrate 91 is depicted prior to the etch operation. At 220, aligned via holes 125a and 125b are formed, but they have not yet broken through to create a completed through-glass via hole. At 230, there is breakthrough and aligned via holes 125a and 125b are connected to form a through-glass via hole 122. However, the contour of the through-glass via hole 122 is not sufficient to allow single-sided line-of-sight deposition from an overhead target. This is shown by tangent line 190 that is tangent to a sidewall of via opening 187a near the intersection of via holes 125a and 125b, and which does not extend through the opening of via hole 125a in the top surface of glass substrate 91. At 240, the etch has proceeded long enough such that the minimum etch radius, R_{Min}, is reached as shown by tangent line 190 just clearing the via opening of via hole 125a (but not yet clearing mask 189a). The etch is permitted to proceed and contour the via holes, and at 250, tangent line 190 extends through the interior of the via opening to form a direct line-of-sight region 192 near the intersection of via holes 125a and 125b. Note that a line (not shown) that is tangent to a sidewall of via hole 125a near the intersection of via holes 125a and 125b may extend through the opening of via 125b.

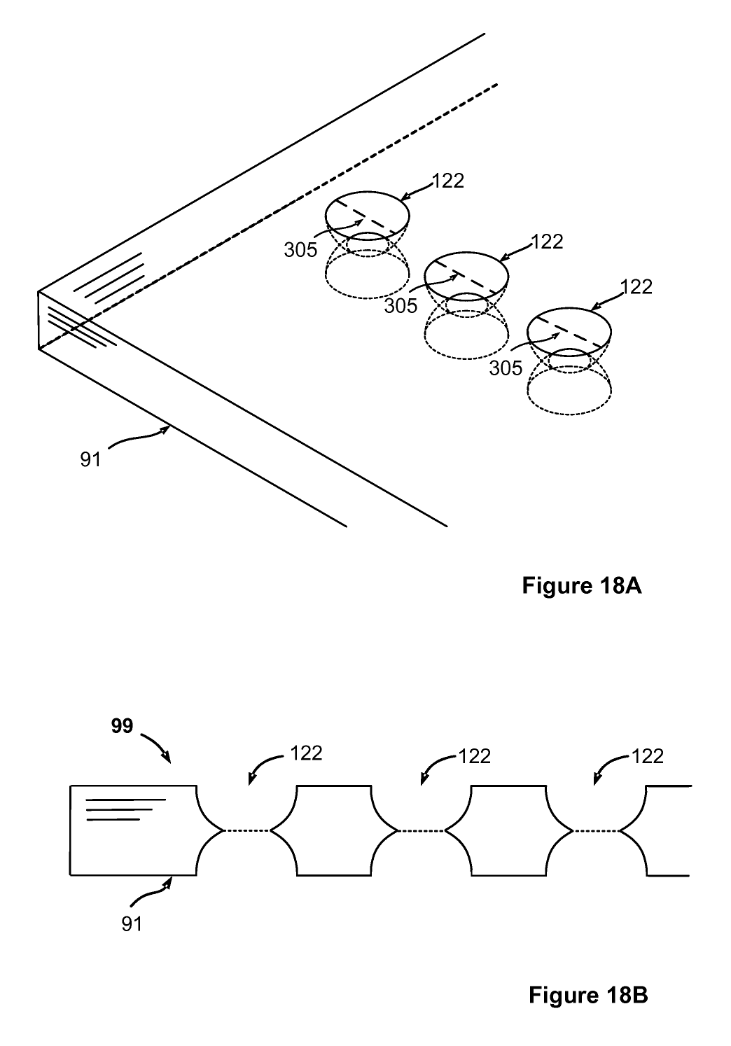

FIGS. 18A-20B present examples of isometric and cross-sectional views of implementations of circular, slot-shaped, and square-shaped through-glass via holes prior to metallization and dicing. FIGS. 18A and 18B provide an isometric view and a cross-sectional view, respectively, of a glass substrate 91 having an array of circular through-glass via holes 122. Through-glass via holes 122 have hemispherically shaped sidewalls that may be fabricated using a double-sided isotropic wet etch process with, for example, a thickness of 500 microns, a mask opening dimension of 10 microns, and an etch radius of 288 microns (R_{Min} as calculated using Equation 1). With these parameters, upper and lower surface via hole opening diameters as given in Table 1 are each 586 microns and the mid-surface intersection diameter is 294 microns. Other parameters can be used according to the desired implementation. Via opening size and other dimensions of the through-glass via size can also vary depending on the desired implementation and particular etch process used. For example, in some implementations in which there is accelerated etching under the mask, the opening diameter can be larger. A center line 305 of each through-glass via hole 112 is indicated. The glass substrate 91 can be cut along the center lines 305 to provide peripheral through-glass via holes.

FIGS. 19A and 19B provide an isometric view and a cross-sectional view, respectively, of a device 99 with a slot-shaped through-glass via hole 122 that may be fabricated using an isotropic wet etch process of a glass substrate 122 having, for example, a thickness of 500 microns, a mask opening dimension of 10×1000 microns, and an etch radius of 288 microns (R_{Min} as calculated using Equation 1). With these parameters, upper and lower surface via opening dimensions as given in Table 2 are each 586×1576 microns, and intersection dimensions are 294×1284 microns. Other parameters can be used according to the desired implementation. Via opening size and other dimensions of the through-glass via size can also vary depending on the desired implementation and particular etch process used. A center line 305 of through-glass via hole 112 is indicated. The glass substrate 91 can be cut along the center line 305 to provide two peripheral through-glass via holes.

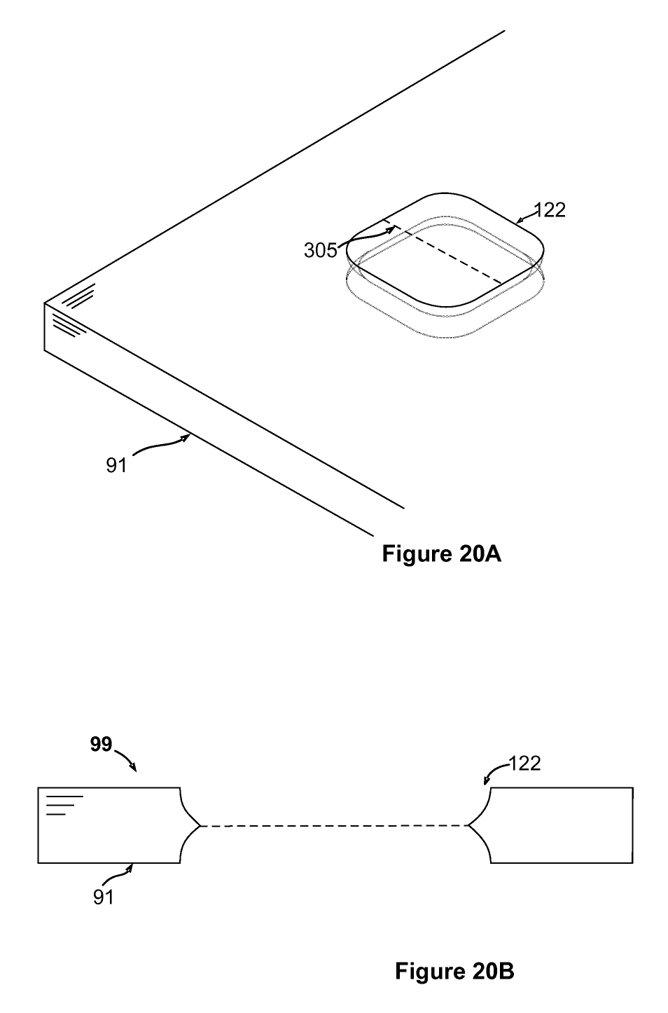

FIGS. 20A and 20B provide an isometric view and a cross-sectional view, respectively, of a device 99 with a square-shaped through-glass via hole 122 that may be fabricated using an isotropic wet etch process of a glass substrate 91 having, for example, a thickness of 500 microns, a mask opening dimension of 1500×1500 microns with corner radii of 250 microns, and an etch radius of 288 microns (R_{Min} as calculated using Equation 1). Via opening dimensions at the upper and lower surfaces are 2076×2076 microns, and via intersection dimensions are 1786×1786 microns, for a uniform double-sided isotropic wet etch under the above-stated assumptions governing Equation 1. Other parameters can be used according to the desired implementation. Via opening size and other dimensions of the through-glass via size can also vary depending on the desired implementation and particular etch process used. A center line 305 of through-glass via hole 122 is indicated. The glass substrate 91 can be cut along the center line 305 to provide two peripheral through-glass via holes.

Once through-glass via holes are formed, the sidewalls can be metallized. As described above, in some implementations, multiple metal lines are formed along the sidewall of a via hole. In some implementations, at least one metal line is formed on either side of a center line of a via hole, such that after dicing, the resulting peripheral through-glass via holes are both metallized. In some implementations, the sidewalls are metallized such that the dicing street does not include metal. As discussed elsewhere, techniques to metallize include sputtering, chemical vapor deposition, atomic layer deposition, jetting and spraying.

FIGS. 21A-21C show examples of schematic illustrations of sidewall metallization of peripheral through-glass vias. (In some implementations, metallization is performed prior to dicing; for ease of illustration the metallized sidewalls are depicted in FIGS. 21A-21C after dicing and formation of the peripheral through-glass vias. Additional components including topside and bottomside traces, pads and devices are not depicted.) FIG. 21A depicts a schematic illustration of peripheral through-glass vias 93 in a glass substrate 91. Peripheral through-glass vias 93 each include a through-glass via hole 122 and a thin conductive film 310 coating the sidewalls of the through-glass via hole 122. The thin conductive film 310 completely covers the sidewalls in this example and provides a single conductive pathway through the glass substrate 91.

FIG. 21B depicts a schematic illustration of peripheral through-glass vias 93 in a glass substrate 91. In this example, peripheral through-glass vias 93 each include a through-glass via hole 122 and a thin conductive film 310 partially coating the sidewalls of the through-glass via hole 122. The thin conductive film 310 extends through the via hole 310 to provide a conductive pathway from the top of glass substrate 91 to the bottom of glass substrate 91. A portion 312 of the sidewalls of through-glass via hole 122 is uncovered. In some implementations, a portion of the sidewalls is not metallized so that there is no metal in the dicing street. The thin conductive film 310 provides a single conductive pathway through the glass substrate 91.

FIG. 21C depicts a schematic illustration of peripheral through-glass vias 93 in a glass substrate 91. In this example, peripheral through-glass vias 93 each include a through-glass via hole 122 and multiple conductive lines 94 extending through the through-glass via hole. Each conductive line 94 can provide an independent conductive pathway through the glass substrate 91, allowing multiple devices, pads or other electrically active components independent access to each via 93.

Examples of metals that can be used to metallize the sidewalls include copper (Cu), aluminum (Al), gold (Au), niobium (Nb), chromium (Cr), tantalum (Ta), nickel (Ni), tungsten (W), titanium (Ti), palladium (Pd) and silver (Ag). In some implementations, sidewall metallization includes depositing a bilayer including an adhesion layer and second layer such as aluminum, gold, copper or another metal. The second layer acts as the main conductor and/or seed layer. Adhesion layers promote adhesion to the glass substrate. Examples of adhesion layers include chromium (Cr), titanium (Ti), and niobium (Nb). Examples of bilayers include Cr/Cu, Cr/Au and Ti/W. Adhesion layers may have thicknesses of a few nanometers to several hundred nanometers or more. In other implementations, conductive paths are formed on the sidewalls of a via hole using a non-metallic material such as a conductive polymer.

As indicated above, various techniques may be used for sidewall metallization. In some implementations, a thin conductive film is deposited on the sidewalls by one or more of a sputter deposition process or other physical vapor deposition (PVD) process, a chemical vapor deposition (CVD) process, an atomic layer deposition (ALD) process and an evaporation process. One-sided or two-sided deposition processes can be used. For example, in some implementations, sidewall metallization includes a one-sided sputtering process in which a target positioned above one surface or the other of a substrate including a through-glass via hole is sputtered to deposit the target material on the surface of the substrate and on the sidewalls of both the upper and lower via holes. Conductive thin film material enters the through-glass via hole only through the via opening on that surface. In another example, a two-sided process in which material is deposited in a through-glass via hole through each via opening, either simultaneously or sequentially, is used. Formation of via holes contoured to facilitate deposition from an overhead deposition source is described above.

In some other implementations, one or more metal layers are formed by electroless plating or electroplating on a conductive thin film. If plating is performed, a previously deposited layer can be used as a seed layer for a subsequent plating operation. Electroplating may be performed, for example, through a plating mask such as a thick photoresist layer or a dry-resist film laminated to or otherwise formed on one or both sides of the glass substrate. Alternatively, a self-seeding plating method may be used.

Thicknesses of the thin films formed during sidewall metallization can range from less than 0.05 to over 5 microns according to various implementations. In some cases, the thickness of a thin film layer on the sidewalls of a through-glass via hole depends on whether plating is to be performed. In implementations in which a thin film provides the electrical connection through the via (i.e., the via hole is unfilled or filled with a non-conductive material), the film may be deposited to a thickness between about 0.1 and 5 microns, such as 1 micron or 2 microns. In implementations in which a thin film is a seed layer for a plating process, it may be deposited to a thickness of about 0.1 to 0.2 microns. Plating may be used to effectively increase the thickness of the thin metal film in the through-glass via and decrease the via resistance. Plated materials may be used to fill or partially fill the via hole. The thickness of the plated layer may range, for example, from a few microns to hundreds of microns. In some implementations, a plated layer thickness is between about 3 and 30 microns. One having ordinary skill in the art will understand that these thicknesses may be varied depending on the desired implementation.

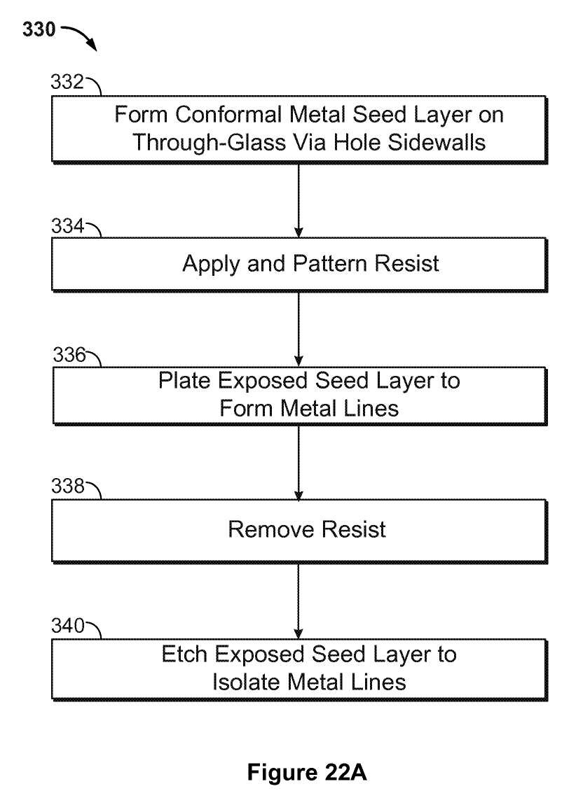

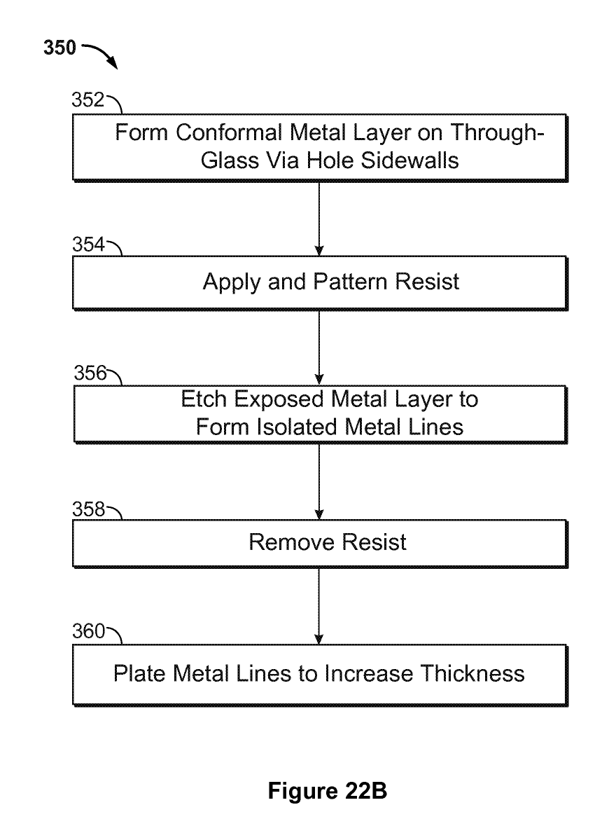

As described above, in some implementations, sidewall metallization includes forming multiple conductive lines or traces inside a through-glass via hole. Various techniques can be used depending on the particular implementation. In some implementations, sidewall metallization can include patterning multiple conductive lines using resists. FIGS. 22A and 22B show examples of flow diagrams illustrating processes for forming multiple conductive lines in a through-glass via hole using patterned resists. First turning to FIG. 22A, a process 330 begins at block 332 with formation of a conformal metal layer on the sidewalls of a through-glass via hole. The metal layer is continuous throughout the through-glass via hole, or at least the portion of the through-glass via hole to be patterned. This operation can involve any conformal deposition processes described above including PVD, CVD, ALD, and evaporation. One-sided or two-sided deposition techniques can be used as described above. In the example of FIG. 22A, the metal layer acts as seed layer for a subsequent plating operation. Examples of metals that can be deposited in block 332 include copper (Cu), gold (Au), nickel (Ni) and combinations thereof. In some implementations, the metal layer can be a bilayer including an adhesion layer and an outer layer. The adhesion layer promotes adhesion to the glass substrate and the outer layer as the seed layer for plating. Examples of adhesion layers include chromium (Cr), titanium (Ti), titanium tungsten (TiW) and niobium (Nb). The total thickness of the deposited layer can be between about 1,000 Angstroms (Å) and 10,000 Å according the desired implementation.

The process 330 continues at a block 334 with application and patterning of a resist on the metal seed layer. In some implementations, an electrophoretic resist (EPR) is used. EPRs are able to be conformally deposited in recessed features, such as through-glass via holes, where spin-coating resist can be difficult. An EPR can be applied by electrodeposition with a potential applied across the conformal metal layer and a counter electrode, followed by rinsing and baking. In other implementations, other types of resists can be used, such as sprayed liquid photoresists. The resist is patterned to expose portions of the metal layer to be plated. This can involve masked exposure and development operations according to the desired implementation. Exposure times may need to be increased to properly expose photoresist on the sidewalls of the through-glass via holes. In part because of depth-of-field focusing issues associated with projection, proximity or contact aligners, the minimum linewidths and spaces attainable within the via may be appreciably larger than that attainable on the surface of the substrate. In some implementations, the resist linewidths can be between about 20 microns and 100 microns, with resist line spacing between about 20 microns and 100 microns according to the desired implementation. The photoresist can be deposited to a nominal thickness of, for example, about 15 to 25 microns thick.

In some implementations, application and patterning of a resist in a via hole is performed on each side of glass substrate, with the photoresist patterned up to a depth of approximately half the thickness of the glass substrate on either side. An EPR, for example, can be used to create a photoresist pattern in a depth of up to 500 microns.

The process 330 continues at block 336 with plating the exposed metal seed layer to form the conductive lines according to the desired implementation. Electroplating or electroless plating can be performed according to the desired implementation. Any appropriate metal can be plated including copper (Cu), nickel (Ni) and Ni alloys, gold (Au), palladium (Pd), and combinations thereof. Examples of plated metal layers include Cu, Cu/Ni/Au, Cu/Ni/Pd/Au, Ni/Au, Ni/Pd/Au, Ni alloy/Pd/Au, Ni alloy/Au. Examples of Ni alloys include nickel cobalt (NiCo) and nickel iron (NiFe). The metal layers are plated to a thickness less than that of the electrophoretic resist. For example, a total plating thickness of 20 microns can be used for a resist thickness of 25 microns. Plating can be performed on a single side at a time or on both sides simultaneously.

The process 330 continues at block 338 with removal of the resist. This operation can involve exposing the resist to an appropriate solvent. Resist can be removed from a single side at a time or from both sides of the glass substrate simultaneously. The process 330 continues at a block 340 with etching the remaining seed layer to electrically isolate the plated metal lines. A wet or dry etch can be used according to the desired implementation. Block 340 can also be performed on a single side at a time or on both sides simultaneously.

In some implementations, a patterned resist is used as an etch mask. FIG. 22B shows an example of a flow diagram illustrating a process for forming multiple conductive lines in a through-glass via hole using a patterned resist as an etch mask. A process 350 begins at block 352 with formation of a conformal metal layer on the sidewalls of a through-glass via hole. The metal layer is continuous throughout the through-glass via hole, or at least the portion of the through-glass via hole to be patterned. This operation can involve any conformal deposition processes described above including PVD, CVD, ALD, and evaporation. One-sided or two-sided deposition techniques can be used as described above. In the example of FIG. 22B, the metal layer acts as the main conductive layer of the metal lines and, in some implementations, as seed layer for subsequent plating to increase the metal line thickness. In some implementations, aluminum (Al) is deposited in block 352. In some implementations, a bilayer including an adhesion layer and an outer layer is deposited, with the outer layer being the main conductive layer of the metal lines and, in some implementations, a seed layer for subsequent plating. Examples of adhesion layers include chromium (Cr), titanium (Ti), titanium tungsten (TiW) and niobium (Nb). The thickness of the conformal metal layer, including an adhesion layer if present, can be between about 1,000 Angstroms (Å) and 10,000 Å according the desired implementation.

The process 350 continues at a block 354 with application and patterning of a resist on the metal layer. In some implementations, an electrophoretic resist (EPR) is used as described above with reference to block 334 of FIG. 22A. In other implementations, other types of resists can be used, such as sprayed liquid photoresists. The resist is patterned to expose portions of the metal layer that will be etched in a subsequent part of the process. In some implementations, the resist linewidths can be between about 20 microns and 100 microns, with resist line spacing between about 20 microns and 100 microns depending on the desired implementation. Note that while the resist pattern formed in block 354 is configured to mask portions of the metal layer that are to remain after patterning, the resist pattern described in block 334 of FIG. 22A is configured to expose portions of the metal layer that are to remain for plating prior to a subsequent etch of the deposited metal (seed) layer.

The process 350 continues at block 356 with etching the exposed metal layer to form isolated metal lines. Block 356 can be performed on a single side at a time or on both sides simultaneously. In some implementations, a reactive ion etch (RIE) process is used to etch the exposed portions of the deposited Al or other metal layer. The process 350 continues at block 358 with removal of the resist. The resist can be removed from a single side at a time or from both sides of the glass substrate simultaneously. In some implementations, the process 350 continues at block 360 with plating the metal lines to increase their thickness. In some implementations, block 360 is not performed. The thickness of the plated layer or layers is between about 2 and 20 microns. Any appropriate metal can be plated including copper (Cu), nickel (Ni), gold (Au), palladium (Pd) and combinations thereof. In some implementations, Ni/Pd/Au layers are plated by an Electroless Nickel—Immersion Palladium—Immersion Gold (ENIPIG) plating chemistry. In some implementations, the thickness of the plated Ni is between about 2 and 10 microns, with Pd and Au thicknesses less than about one micron. In addition to augmenting metal line thickness, the addition of the Pd and Au can facilitate soldering in subsequent processing according to the desired implementation. Block 360 can be carried out on one side and then repeated on the second side, or can be carried out on both sides simultaneously.

In some implementations, multiple conductive lines are formed in via hole by a maskless direct writing process. The particular technique used can depend on the desired pattern density. For example, for a linewidth of about 200 microns or greater, at a 400 micron pitch or greater, a jet such as the Nordson ASYMTEK DJ-9000 dispense jet or similar jet can be used to dispense an electrically conducting paste. After dispensation, the paste is cured to form the lines. The processing is carried out on one side and then repeated on the other side of the glass substrate.

For a denser line pattern, a system such as the Optomec Aerosol Jet® system can be used to dispense electrically conducting colloidal metal aerosol on the sidewall of the through-glass via hole. The silver metal in the colloid is sintered into a conducting silver trace by a thermal bake. Metal lines having widths as low as 20 microns, with a line spacing as low as 20 microns, can be written using such as system. This process can also be used to make multiple passes to increase the thickness of the metal trace and can be used for coarser metal geometry as well.

In some implementations, a through-glass via hole is large enough to accommodate a jet. For example, the smallest dimension of a slot-shaped via hole can be the mid-surface width. If a jet head requires 200 microns, the mid-surface width or other appropriate dimension is at least 200 microns. Minimum wet etch radii for desired dimensions can be determined as described above with reference to FIG. 16 and Tables 1 and 2.

In some implementations, the glass substrate is diced after sidewall metallization. In some other implementations, sidewall metallization can be performed after dicing. In some implementations, the via opening size allows standard die-cutting processes to be used without losing the entire via to kerf and other cutting-related loss. As described above, through-glass via holes are formed in an interior region of a large glass substrate. Prior to dicing, a glass substrate can include tens, hundreds, thousands or more through-glass vias described herein, each of which is shared by two or more dies as described above with reference to FIG. 9C. Dicing the substrate to form individual dies involves cutting through the as-formed via holes such that a single via hole forms a peripheral via on two adjacent dies. In some implementations, material loss from die cutting can be about 100 microns, though one having ordinary skill in the art will understand that this can vary according to the desired implementation. Via hole widths, diameters or other opening dimension greater than the material loss from die cutting allow an as-formed via to be cut into two peripheral vias while tolerating the material loss.

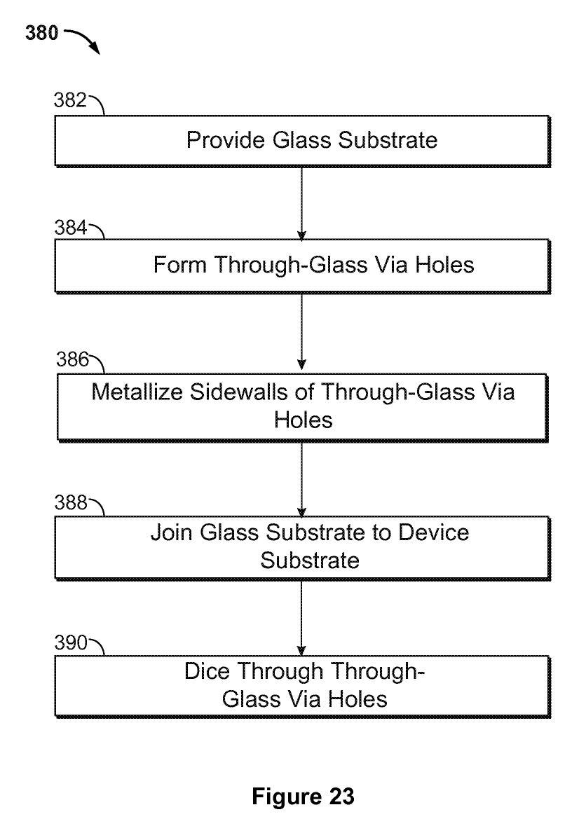

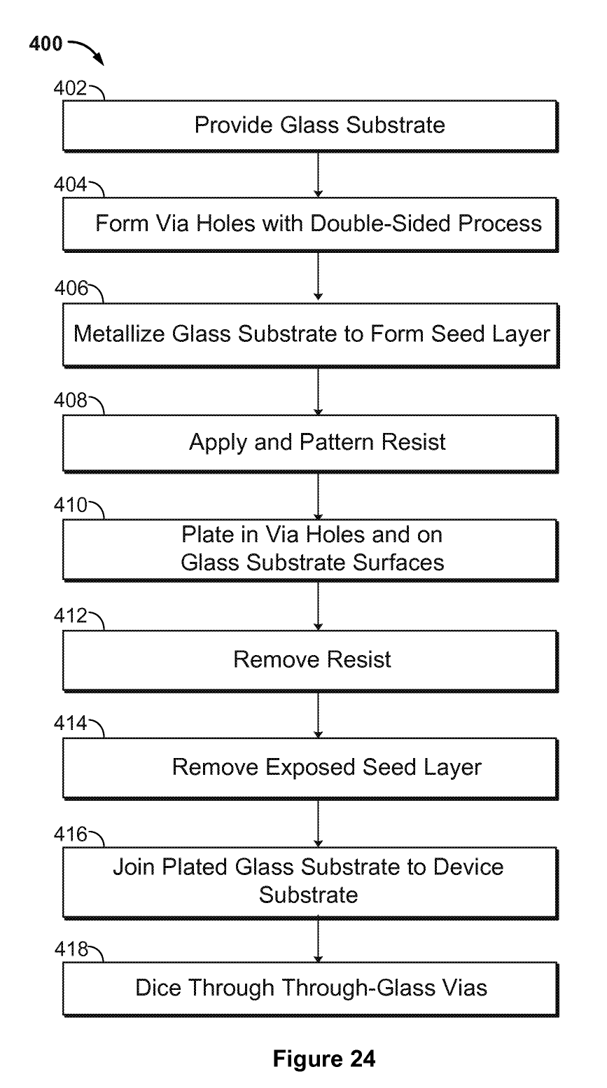

As indicated above, the peripheral through-glass vias and methods of fabrication described herein may be applied to any glass substrate, including glass substrates on which MEMS or other devices are fabricated and glass substrates used to encapsulate MEMS or other devices. FIGS. 23 and 24 show examples of flow diagrams illustrating processes for fabricating a glass package including a peripheral through-glass via. While the description that follows focuses implementations using glass substrates, it is understood that other substrates, such as non-glass insulating substrates, also may be used. In some implementations, the processes described with reference to FIGS. 23 and 24 can be batch level processes in which all or at least a plurality of devices fabricated on a device substrate are encapsulated as a batch. In some other implementations, the processes can include non-batch processes. Batch level processes involve encapsulating a plurality of devices simultaneously and can be performed at a panel, wafer, substrate, sub-panel, sub-wafer, or sub-substrate level. For example, tens, hundreds, thousands or more electromechanical systems devices may be fabricated on a single device substrate. Certain operations in a batch level encapsulation process are performed once for a plurality of devices, rather than performed separately for each device.

First turning to FIG. 23, a process 380 begins at block 382 with providing a glass substrate. In some implementations, the glass substrate is thick enough to provide mechanical protection to an encapsulated electromechanical device. In some implementations, process 380 may be useful where the glass substrate serves as a back glass with integrated electrical connectivity for a device formed on a device substrate. This can allow for providing electrical connection between passive or active devices integrated onto the glass substrate and the device formed on the device substrate. Active devices integrated onto the glass substrate can include driver and/or wireless communication chips. In some implementations, the glass substrate is between about 300 and 700 microns. In some implementations, the glass substrate is at least about 500 microns. The glass substrate may be any appropriate area. In some implementations, the glass substrate has approximately the same area and shape as a device substrate that supports the devices to be encapsulated. In some implementations, a glass substrate (sometimes referred to as a glass plate or panel) having an area on the order of four square meters or greater is provided with a thickness, for example, of 0.3, 0.5, or 0.7 millimeters. Alternatively, round substrates with diameters of 100 millimeters, 150 millimeters, or other diameters may be provided. In some other implementations, square or rectangular sub-panels cut from a larger panel of glass may be provided. The glass substrate may be or include, for example, a borosilicate glass, a soda lime glass, quartz, Pyrex, or other suitable glass material.

In some implementations, the glass substrate is substantially planar having substantially parallel major surfaces (also referred to as top and bottom surfaces). One having ordinary skill in the art will understand that one or both surfaces may also include various recessed or raised features to accommodate, for example, an electromechanical systems device, such as a display device, or an electronic chip or device, such as a wireless communications chip.

The process 380 continues at a block 384 with formation of through-glass via holes. Through-glass via holes can be formed by any appropriate process including one or more of a wet etch, dry etch or sandblast process. In some implementations, a double-side process as described above with reference to FIG. 12 can be used. In some other implementations, a single-sided process can be used. The size and shape of the through-glass via holes can vary according to the desired implementation as described above. Examples of through-glass via opening shapes include slot-shaped via openings, circular via openings, oval via openings, rectangular via openings, square via openings, rectangular or square vias with rounded corners, etc. The two openings of a through-glass via hole can be approximately the same shape and size, or can be different.

In some implementations, the through-glass via holes have sidewalls with a concave curvature extending from the planar glass substrate surface to a point in the interior of the glass. In some implementations, the through-glass via holes have a tapered or v-shaped profile, with the sidewalls tapering from a larger via opening at one surface to a smaller via opening at the other surface. In some implementations, the through-glass via holes have a substantially uniform area throughout the glass substrate, with the via holes having substantially straight, vertical sidewalls. In some implementations, the glass substrate is also processed to define features other than through-glass via holes. For example, a recess to accommodate an electromechanical systems device can be etched.

The process 380 continues at block 386 with metallization of the sidewalls of through-glass via holes. Metallization of through-glass via holes can be a one-sided or two-side process involving one or more sputter deposition process or other physical vapor deposition (PVD) process, a chemical vapor deposition (CVD) process, an atomic layer deposition (ALD) process, an evaporation process, an electroless plating process, an electroplating process, a jetting process and a spraying process as well as one or more patterning operations as described above with reference to FIGS. 21A-21C and FIG. 22. In some implementations, the top and/or bottom surface of the glass substrate is also metallized to form, for example, bond pads, traces and the like.

The process 380 continues at block 388 with joining the glass substrate to the device substrate. The glass substrate covers one or more electromechanical systems devices on the device substrate. Joining techniques include solder bonding, eutectic metal bonding, adhesive bonding including epoxy bonding, and thermocompression bonding. In some implementations, a joining material is applied to one or both of the glass substrate and the device substrate prior to joining Examples of joining materials include solder paste or other solderable material, a eutectic alloy, and an epoxy or other adhesive material. Joining process conditions such as temperature and pressure can vary according to the particular joining method and desired characteristics of the encapsulation area. For example, for eutectic or solder bonding, the joining temperature can range from about 100° C. to about 500° C. as appropriate. Example temperatures are about 150° C. for indium/bismuth (InBi) eutectic, 225° C. for copper/tin (CuSn) eutectic, and 305° C. for gold/tin (AuSn) eutectic.

Epoxy can be used for a hermetic or non-hermetic seal around the electromechanical systems device and solder joining can be used for a hermetic seal. The width of the seal can vary according to method of joining and the desired implementation. In some implementations, the width is between about 50 and 200 microns.

In some implementations in which solder or eutectic joining is performed, a width of about 50-100 microns can be sufficient to provide an adequate seal. In some implementations, the width can vary depending on the method by which joining ring solder material is formed. For seals having widths of about 200 microns or greater, screen printing can be used. For narrower seals, such as 50-150 microns, plating can be used. In some implementations in which an epoxy or polymer adhesive is used, the width of the joining area can be larger, such as around 500 microns, to provide a hermetic seal according to the desired implementation. In some implementations, the target width of the seal is increased to accommodate CTE mismatch between a device substrate and a carrier substrate during the joining process.

The process 380 continues at block 390 with dicing the joined substrates to form individual dies of electromechanical systems devices on a device substrate bonded to glass substrates with peripheral through-glass vias. The substrates are diced such that the dicing streets go through at least some of the through-glass vias as described above with respect to FIG. 9C. The individual dies, each having an encapsulated electromechanical systems device, can be further packaged, for example with an application specific integrated circuit (ASIC). For example, a die can be positioned on an integration substrate such as a printed circuit board (PCB) or other substrate to which the encapsulated device is to be electrically connected. In some implementations, an ASIC also is positioned on the integration substrate. The die and ASIC can be positioned in a side-by-side or stacked configuration. An electrical connection between the die and the integration substrate can be formed by wire bonding, flip-chip attachment or other method, and may, in some implementations, use metalized peripheral through-glass vias to allow electrical connection to the device on the device substrate.

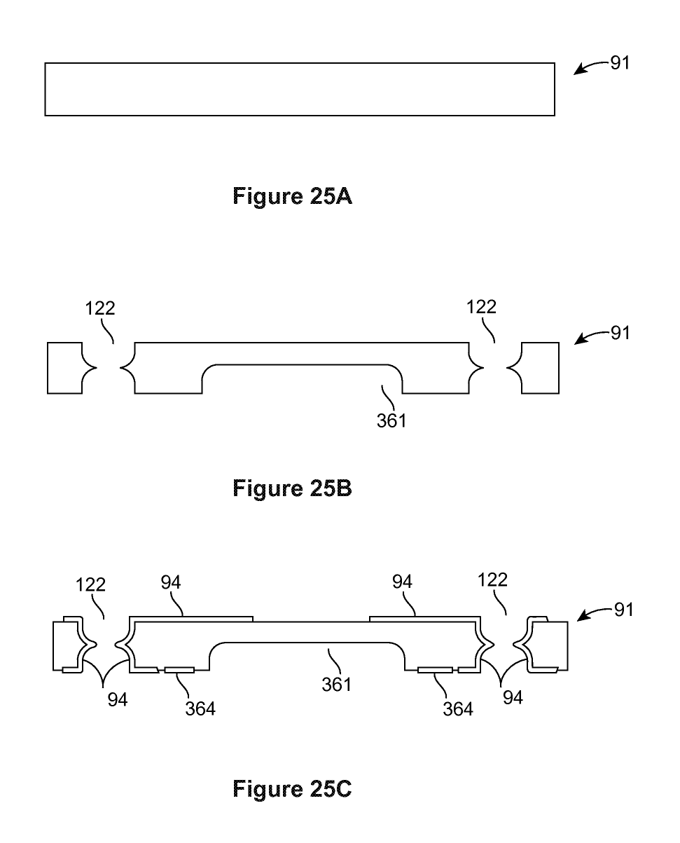

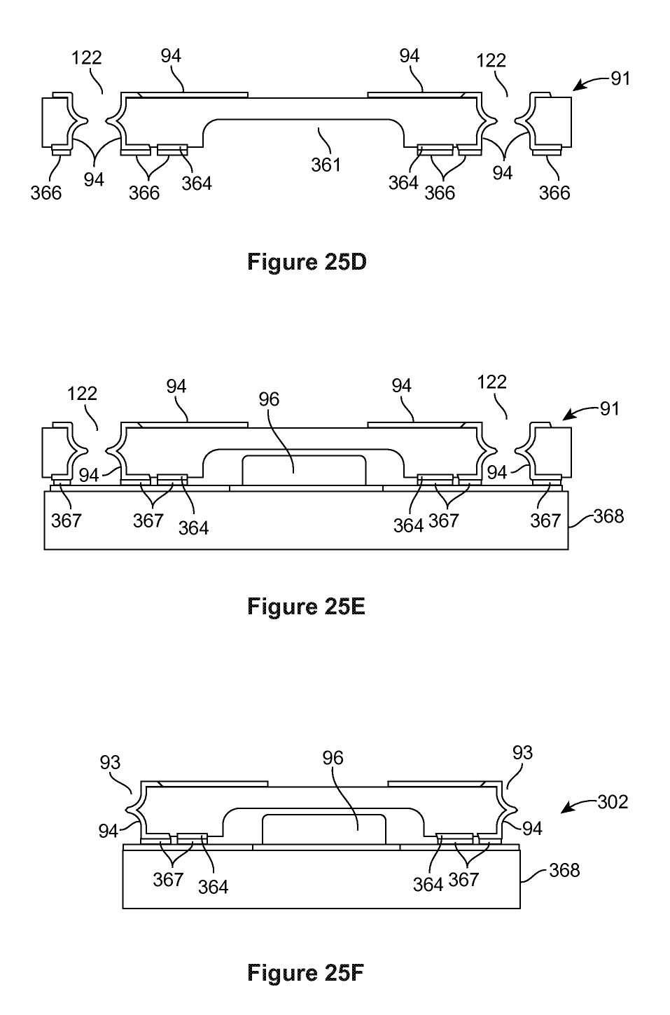

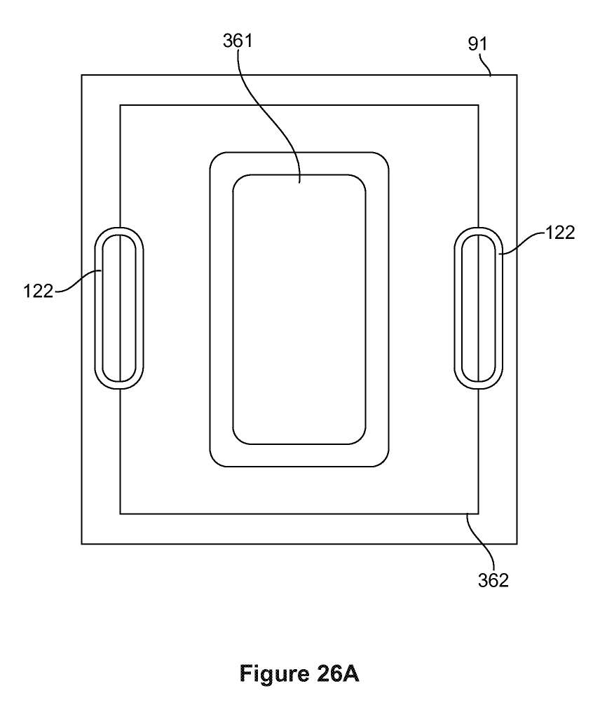

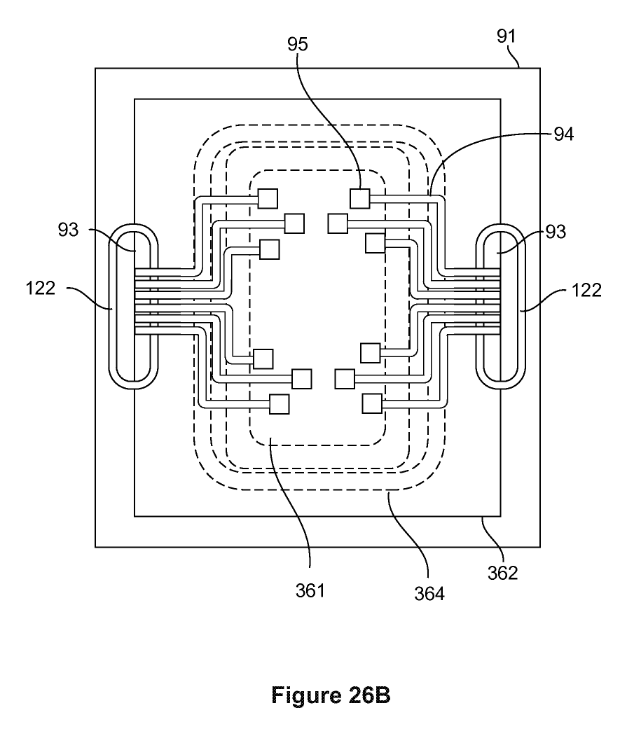

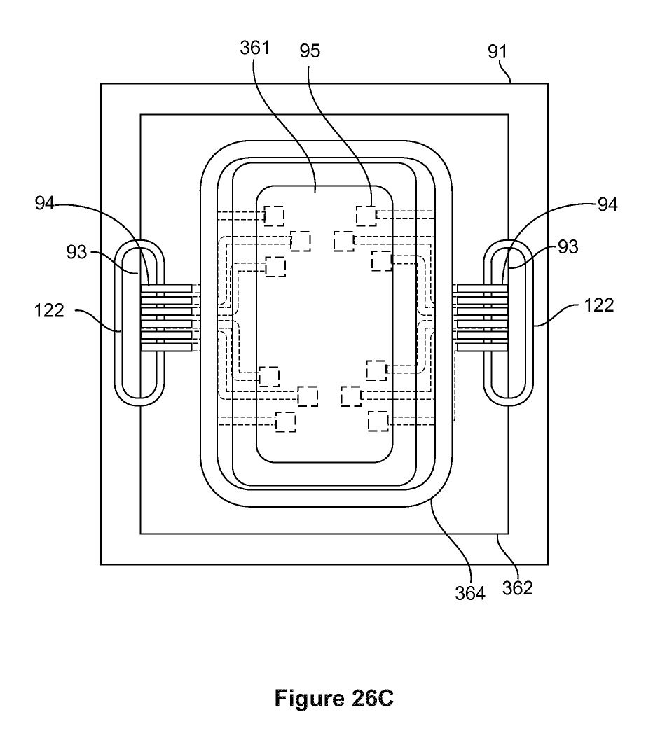

FIG. 24 shows an example of a flow diagram illustrating an implementation of the process shown in FIG. 23. FIGS. 25A-25F and 26A-26C show examples of schematic illustrations of various stages in a method of fabricating a glass package including a peripheral through-glass via.

First turning to FIG. 24, a process 400 begins at block 402 with providing a glass substrate. FIG. 25A shows a cross-sectional depiction of a portion of a glass substrate 91. Glass substrate 91 can have a thickness of between about 300 and 700 microns in some implementations. The process 400 continues at block 404 with formation of through-glass via holes by a double-sided process as described above with respect to FIG. 12. The through-glass via holes are positioned such that they will be located on the periphery of a die after dicing. FIG. 25B shows glass substrate 91 after formation of through-glass via holes 122. Glass substrate 91 includes an etched recess 361 to accommodate an electromechanical systems device. FIG. 26A provides a bottom view of a portion of a glass substrate 91 prior to metallization and including through-glass via holes 122 and etched recess 361. Portion 362 indicates the dimensions of a die including etched recess 361. In some implementations, portion 362 is a repeating unit of a glass substrate configured to cover a plurality of devices on a device substrate.

The process 400 continues at block 406 with metallization of the glass substrate to form a seed layer for plating. The seed layer is formed on both top and bottom surfaces of the glass substrate, as well as on the sidewalls of the through-glass via holes. In some implementations, the seed layer is formed by sputter deposition of an adhesion layer on the glass substrate, followed by sputter deposition of the seed layer. The process is performed for top and bottom sides of the glass substrate to deposit a seed layer on both top and bottom surfaces, connected by a continuous seed layer formed on the through-glass via hole sidewalls.

The process 400 continues at block 408 with application and patterning of one or more resists in the through-glass via holes and top and bottom surfaces of the glass substrate. The one or more resists are patterned to define one or more conductive lines in the through-glass via holes and bond pads, conductive lines and the like on the top and bottom surfaces according to the desired implementation. In some implementations, the same type of resist application and development process is used for the through-glass via holes and the top and bottom surfaces. In some other implementations, two or more different types of resists are used. In some implementations, an electrophoretic resist (EPR), as described above, is used to pattern the through-glass via hole sidewalls. An EPR can also be used to pattern the top and bottom surfaces. In some implementations, a laminate resist can be used to pattern the top and bottom surfaces. One example of such a resist is DuPont® MX5000 dry film photoresist.

The process continues at block 410 with plating on the through-glass via hole sidewalls and on the top and bottom surfaces and on the sidewalls. Conductive lines in the through-glass via holes as well as bond pads and the like on the top and bottom surfaces can be formed by electroplating or electroless plating according to the desired implementation. In some implementations, nickel (Ni) or a Ni alloy is plated. Other examples of metals that can be plated to form the conductive lines and bonds pads include copper (Cu), copper (Cu) alloys, aluminum (Al), aluminum (Al) alloys, tin (Sn), tin (Sn) alloys, titanium (Ti) and titanium (Ti) alloys.

After plating, the process 400 continues at a block 412 with removal of the one or more resists. The one or more resists may be removed by a technique appropriate for the particular resist(s) used. This operation can include post-removal cleans of resist related residue. The process 400 continues at block 414 with etch of the exposed seed layer, i.e., the portion of the seed layer masked by the resist during plating. Etching of the exposed seed layer is performed with an etchant that is selective to the seed layer, without etching the plated metal. Selective etchants include etchants that have selectivity of at least about 100:1 or higher for the exposed seed layer. Specific examples of etchants for selective etching of copper seed layers include a mixture of acetic acid (CH₃CO₂H) and hydrogen peroxide (H₂O₂), and ammoniacal-based etchant such as BTP copper etchant from Transene Company, Inc. in Danvers, Mass.

FIG. 25C is an example of a cross-sectional schematic depiction of glass substrate 91 after plating and removal of resist and exposed seed layer. Conductive lines 94 extend through through-glass via holes 122 and connect the top and bottom sides of the glass substrate 91. A bond ring 364 on the bottom side of glass substrate 91 is plated to provide a point of attachment to a device substrate in subsequent processing. FIGS. 26B and 26C provide top view and bottom views, respectively, of glass substrate 91, after plating and removal of resist and exposed seed layer. FIG. 26B depicts conductive lines 94 from through-glass via holes 122 and connected to topside bond pads 95. Topside bond pads 95 are staggered to allow increased metal line density. In the depicted example, each through-glass via hole includes six conductive lines 94. As an example, the pitch of the lines can be 70 microns. FIG. 26C depicts conductive lines 94 extending from through-glass via holes 122 and bond ring 364 surrounding etched recess 361. Bond ring 364 can be, for example, about 50-200 microns wide. Conductive lines 94 are configured to connect to leads from an electromechanical systems device or other component on a device substrate. Although not depicted in the Figure, each through-glass via hole may include another set of conductive lines extending to another set of bonds pads on an adjacent die.

Returning to FIG. 24, the process 400 continues at block 416 with joining the plated glass substrate to the device substrate. FIG. 25D depicts glass substrate 91 with eutectic solder material 366 disposed on conductive lines 94 and bond ring 364. Examples of eutectic alloys that can be used include indium/bismuth (InBi), tin/indium (SnIn) and tin/bismuth (SnBi), which have a eutectic temperature around 150° C. FIG. 25E is an example of a cross-sectional schematic depiction of glass substrate 91 joined to a device substrate 368. Joining ring 364 and conductive lines 94 are bonded to device substrate 368 after solidification of the diffused solder material 367. Although depicted as distinct layers, it is understood that the bonded joining ring 364 and bonded portions of the conductive lines 94 can form an alloy with the diffused solder material 367. MEMS device 96 is encapsulated by glass substrate 91, and electrically connected to the topside of glass substrate 91 by metal lines 94 in the through-glass via hole 122. The process 400 continues at block 418 with dicing through the through-glass vias as described above to form peripheral through-glass vias. FIG. 25F depicts die 302 including encapsulated MEMS device 96 and peripheral through-glass vias 93. MEMS device 96 can be any appropriate device including a gyroscope, accelerometer, pressure sensor, microphone, microspeaker or other MEMS device according to the desired implementation. In some implementations, dicing is performed such that the dicing streets are outside of the through-glass vias. In these embodiments, a cross-section of a resulting individual die can look like the cross-section depicted in FIG. 25E.

Although the above description refers chiefly to packaging of MEMS devices, one having ordinary skill in the art will understand that the peripheral through-glass vias, methods of fabricating them and related packaging methods described above can also be implemented in other contexts, packaging of other devices including other electromechanical systems devices and integrated circuit devices, or any context in which a conductive pathway through a glass substrate is desired.

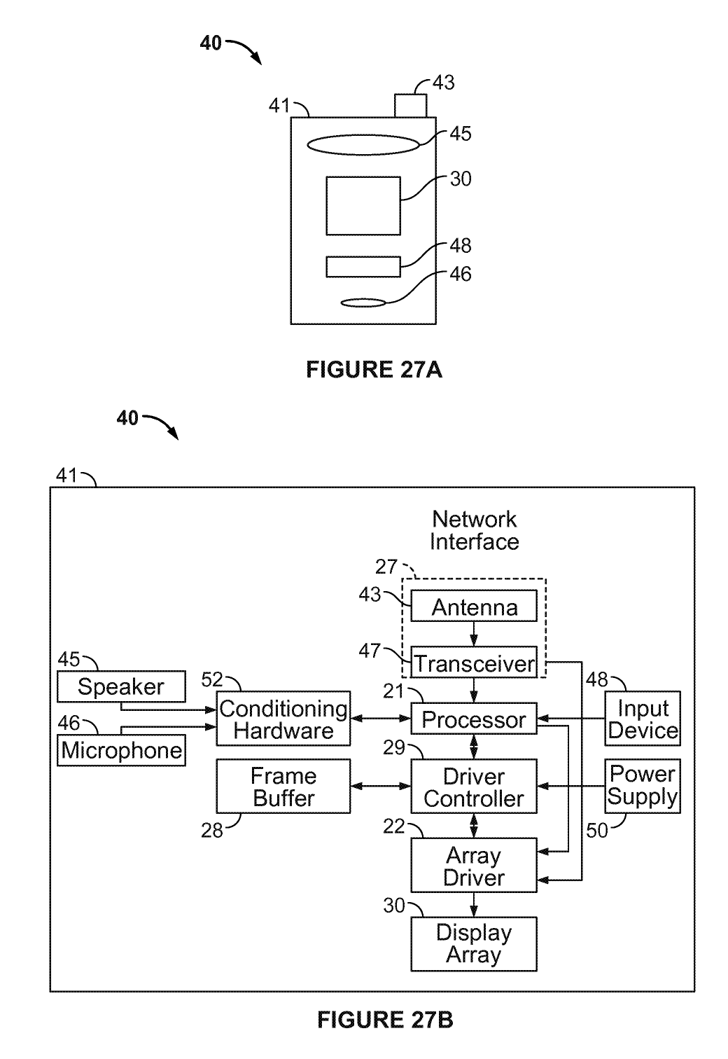

In some implementations, the peripheral through glass vias can be used to provide electrical connections to interferometric modulators. FIGS. 27A and 27B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 27B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those having ordinary skill in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

The through-glass vias and processing methods described herein may be implemented in various packages for MEMS devices. Moreover, the methods and devices described herein are not limited to packaging of MEMS or other devices, but may be used to provide a path through any glass substrate.

What is claimed is:

1. An apparatus comprising:
a glass substrate having top and bottom surfaces and a plurality of side surfaces substantially orthogonal to and connecting the top and bottom surfaces; and
a first through-glass via including via openings in the top and bottom surfaces, the first through-glass via having a sidewall and a plurality of electrically conductive lines extending along the sidewall from the top surface to the bottom surface.

2. The apparatus of claim 1, wherein the sidewall is recessed from at least a first one of the plurality of side surfaces.

3. The apparatus of claim 1, wherein the sidewall includes a first surface extending from the top surface and a second surface extending from the bottom surface, wherein the first and second surfaces intersect at an intersection.

4. The apparatus of claim 1, wherein the first and second surfaces are each curved from a via opening to the intersection.

5. The apparatus of claim 2, further comprising:
a second through-glass via including via openings in the top and bottom surfaces, the second through-glass via having a sidewall recessed from a second one of the plurality side surfaces and a plurality of electrically conductive lines extending along the sidewall from the top surface to the bottom surface.

6. The apparatus of claim 1, further comprising a second substrate joined to the glass substrate.

7. The apparatus of claim 6, further comprising an electromechanical systems device disposed on the second substrate and in electrical communication with at least some of the plurality of electrically conductive lines.

8. The apparatus of claim 7, further comprising a seal between the glass substrate and the second substrate.

9. The apparatus of claim 8, wherein the electromechanical systems device is sealed within an area defined at least in part by the glass substrate, the second substrate and the seal.

10. The apparatus of claim 8, wherein the seal includes a solder bond or an epoxy bond.

11. The apparatus of claim 1, further comprising an electromechanical systems device disposed on the glass substrate and in electrical communication with at least some of the plurality of electrically conductive lines.

12. The apparatus of claim 1, wherein at least some of the plurality of electrically lines are in electrical communication with bond pads disposed on the top or bottom surface of the glass substrate.

13. The apparatus of claim 12, wherein the bond pads are arranged in a staggered formation.

14. The apparatus of claim 1, wherein the plurality of lines have a pitch of no more than about 400 microns.

15. The apparatus of claim 1, wherein the via openings are half-slot shaped.

16. The apparatus of claim 1, further comprising:
a display;
a processor that is configured to communicate with the display, the processor being configured to process image data; and
a memory device that is configured to communicate with the processor.

17. The apparatus of claim 16, further comprising:
a driver circuit configured to send at least one signal to the display; and
a controller configured to send at least a portion of the image data to the driver circuit.

18. The apparatus of claim 16, further comprising:
an image source module configured to send the image data to the processor.

19. The apparatus of claim 16, wherein the image source module includes at least one of a receiver, transceiver, and transmitter.

20. The apparatus of claim 16, further comprising:
an input device configured to receive input data and to communicate the input data to the processor.

21. An apparatus comprising:
a glass substrate having first and second sides;
a device mounted to the first side of the glass substrate; and
means for electrically connecting the device to the second side of the glass substrate.

22. The apparatus of claim 21, further comprising an electrical component on the second side of the glass substrate, and wherein the means for electrically connecting the device to the second side of the glass substrate include means for electrically connecting the device to the electrical component.

23. A method, comprising:
providing a glass substrate having first and second parallel surfaces;
forming a first via hole in the first surface and a second via hole in the second surface, wherein the first and second via holes intersect to form a through-glass via hole having via openings on the first and second surfaces and an intersection dimension that is less than a corresponding dimension at each via opening;
forming a plurality of electrically conductive lines that are continuous through the through-glass via hole from the first surface to the second surface; and
dicing the glass substrate along a line that passes through the through-glass via hole.

24. The method of claim 23, wherein forming the first and second via holes includes exposing the first and second surfaces to a wet etchant to form the first via hole on the first surface and the second via hole on the second surface.

25. The method of claim 24, wherein forming the first and second via holes includes forming a mask on each of the first and second surfaces, the masks having at least one opening with a smallest mask opening dimension d_{M}.

26. The method of claim 25, wherein forming at least one of the first and second via holes includes exposing the glass substrate to the wet etchant, wherein an etch radius R of the first and second via holes satisfies R≧R_{Min} where R is the etch radius; and
R_{Min}=(√2)(t_{S}/2)/(1+((d_{M}+R_{Min})/R_{Min})(1−(t_{S}/2R_{Min})²)^{1/2})^{1/2}
and where t_{S} is a thickness of the glass substrate.

27. The method of claim 23, wherein forming the first and second via holes includes aligning stencil patterns on the first surface and second surface of the glass substrate and sandblasting the glass substrate in accordance with the aligned stencil patterns.

28. The method of claim 23, wherein forming a plurality of electrically conductive lines that are continuous through the through-glass via hole from the first surface to the second surface includes applying an electrophoretic resist in the through-glass via hole.

29. The method of claim 23, wherein forming a plurality of electrically conductive lines that are continuous through the via hole from the first surface to the second surface includes performing a maskless additive metal jetting process.

30. The method of claim 22, further comprising joining the glass substrate to a second substrate prior to dicing.

31. The method of claim 23, further comprising metallizing at least one of the first and second surfaces to form one or more bond pads in electrical communication with the one or more continuous conductive lines.
